(19) United States
(12) Patent Application Publication
(10) Pub. No.: US 2006/0040137 A1
(43) Pub. Date: Feb. 23, 2006

(54) ORGANIC EL DEVICE, METHOD OF MANUFACTURING THE SAME, AND ORGANIC EL DISPLAY

(75) Inventors: Emiko Kambe, Atsugi-shi (JP); Akira Ebisawa, Tokyo (JP)

Correspondence Address: OLIFF & BERRIDGE, PLC, P.O. BOX 19928, ALEXANDRIA, VA, 22320, US

(73) Assignee: TDK CORPORATION, TOKYO (JP)

(21) Appl. No.: 11/202,233

(22) Filed: Aug. 12, 2005

(30) Foreign Application Priority Data
Aug. 17, 2004 (JP) P2004-237654
Aug. 17, 2004 (JP) P2004-237650

(51) Int. Cl. H05B 33/14

(52) U.S. Cl. 428/690; 428/917; 313/504; 313/506; 427/66; 257/88; 257/E51.028; 257/E51.033

(57) ABSTRACT

A first organic EL device in accordance with the present invention comprises a pair of electrodes opposing each other and a luminescent layer, disposed between the electrodes, containing a polymer having an anthracene structure; and a hole-transferring compound having a glass transition temperature of at least 70° C. A second organic EL device in accordance with the present invention comprises a hole injection electrode and an electron injection electrode which oppose each other; a luminescent layer, disposed between the hole injection electrode and electron injection electrode, containing a polymer having an anthracene structure and having a modified part, disposed near the surface on the side closer to the electron injection electrode, containing a hole-blocking compound having a bandgap of at least 4.0 eV; and an electron-blocking layer, disposed between the hole injection electrode and the luminescent layer, containing a hole-transferring compound having an electron affinity of 3.0 eV or less. The first and second organic EL devices can keep device characteristics such as luminance and luminous efficiency at a high level for a long period.

### BACKGROUND OF THE INVENTION

1. Field of the Invention

The present invention relates to an organic EL (electroluminescence) device, a method of manufacturing the same, and an organic EL display.

2. Related Background Art

Since the Eastman Kodak Company announced a laminate organic EL device in which organic layers were formed by vacuum deposition using low molecular weight compounds, organic EL displays have been vigorously developed and currently been in the process of becoming practically usable.

On the other hand, from the viewpoint of excellent heat stability and the like, the development of organic EL devices using polymer compounds as constituent materials of organic layers has actively been underway. Using a polymer compound in an organic layer is not only excellent in heat stability, but also advantageous in that the manufacturing process can be simplified since the organic layer is mainly formed by a coating method using a coating solution. Further, while the organic layer formed by using the vacuum deposition tends to lack a part thereof and cause defects, the organic layer formed by the coating method is quite hard to cause defects and thus is advantageous in yielding a relatively high reliability.

In general, polymer compounds used in organic EL devices are roughly divided into π-conjugated polymers (see, for example, Japanese Patent Application Laid-Open No. 2003-338375) and non-π-conjugated polymers (see, for example, Applied Physics Letters, vol. 51, p. 913 (1987)). Among them, the non-π-conjugated polymers have such a high degree of freedom in molecule designing that, for example, a predetermined characteristic can be imparted thereto if a structure (anthracene structure, fluoranthene structure, or the like) is introduced as a side chain group into a polymer chain. Forming a luminescent layer by adding a predetermined dopant to a non-π-conjugated polymer employed as a host material is advantageous in that an aimed color can be obtained with a high color purity.

### SUMMARY OF THE INVENTION

Recently, however, organic EL devices have been demanded to improve their device characteristics further, so that the above-mentioned conventional organic EL devices still have room for improvement in order to respond to such demands. In particular, the conventional organic EL devices using non-π-conjugated polymers are not considered to have a sufficient life, so that their device characteristics such as luminance and luminous efficiency deteriorate in a relatively short time.

In general, a polymer EL device is hard to attain a laminate structure without affecting other layers, since its luminescent layer is formed by applying a polymer compound, whereby those having an organic layer of a single-layer structure have been employed except for PEDOT/PSS which is a water dispersion type system constituting a hole-injecting layer. In an organic EL device whose organic layer has a single-layer structure, its single organic layer is required to exhibit all the functions of carrier transfer, carrier recombination, and luminescence. However, because of deviations in carrier balance and the like, the organic EL devices using the conventional polymer compounds cannot effectively exhibit all such functions, and thus are not always satisfactory in terms of device characteristics such as luminous efficiency, heat resistance, and life. Consequently, organic EL devices using polymer compounds having excellent device characteristics are still in demand from the viewpoints of reliability in the manufacturing process (yield), manufacturing cost, and the like,

In view of the problems in the prior art mentioned above, it is an object of the present invention to provide a long-life organic EL device which can keep device characteristics such as luminance and luminous efficiency at a high level for a long period, a method of manufacturing the same, and an organic EL display.

For solving the above-mentioned problems, in one aspect, the present invention provides an organic EL device (hereinafter referred to as “first organic EL device”) comprising a pair of electrodes disposed so as to oppose each other; and a luminescent layer, disposed between the electrodes, containing a polymer having an anthracene structure and a hole-transferring compound having a glass transition temperature of at least 70° C.

The above-mentioned first organic EL device is achieved according to the following findings discovered by the inventors. Namely, in the conventional organic EL devices using a non-π-conjugated polymer, the carrier mobility in the luminescent layer greatly differs between a hole and an electron, so that their equilibrium (carrier balance) is likely to be lost. In particular, the number of electrons tends to become smaller than that of holes. Therefore, it seems that the holes and electrons are less likely to recombine with each other in the luminescent layer, so that device characteristics such as luminance and luminous efficiency deteriorate. By contrast, the above-mentioned first organic EL device causes the luminescent layer to contain a polymer having an anthracene structure and a hole-transferring compound having a glass transition temperature of at least 70° C., thus making it possible to keep device characteristics such as luminance and luminous efficiency at a high level for a long period, whereby a long-life organic EL device can effectively be realized.

Though the reason why the first organic EL device achieves the effects mentioned above is not definitely clear, the inventors presume as follows.

Namely, it seems that the hole-transferring compound is held within the polymer having the anthracene structure in the luminescent layer in the first organic EL device, so that each carrier mobility is enhanced without increasing the difference between the hole mobility and electron mobility. Therefore, it is deemed that the carrier balance can be kept in a favorable state so that the holes and electrons efficiently recombine with each other, whereby device characteristics such as luminance and luminous efficiency can be kept at a high level for a long period.

Also, since the luminescent layer contains a polymer having an anthracene structure and the hole-transferring compound having a glass transition temperature of at least 70° C., it seems that characteristics such as voltage endurance, heat resistance, and oxidation resistance of the luminescent layer are fully enhanced, whereby the carrier balance improving effect achieved by using both of the two ingredients mentioned above can be obtained even when the device is driven for a long period or repeatedly.

In the above-mentioned first organic EL device, the luminescent layer is preferably formed by a coating method using a coating liquid containing the above-mentioned polymer and hole-transferring compound, and is more preferably annealed. In the manufacturing process of an organic EL device, heating (annealing) the luminescent layer formed by the coating method is effective in attaining a longer life. However, the luminescent layers of the conventional organic EL devices do not always have a favorable heat resistance, and thus may fail to emit light or shorten their life after being annealed. By contrast, the above-mentioned first organic EL device can attain a high level of life improving effect by the annealing, since the luminescent layer has a sufficient heat resistance as mentioned above.

Preferably, in the first organic EL device, the above-mentioned polymer contained in the luminescent layer contains at least one species selected from the structure units represented by the following general formulas (1) to (4). Using a polymer having such a structure unit can effectively realize a long-life organic EL device which can keep device characteristics such as luminance and luminous efficiency at a high level for a long period. 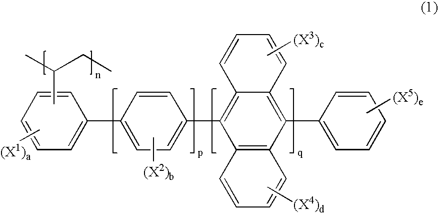
where X¹, X², X³, X⁴, and X⁵ are either identical or different from each other, each representing an alkyl group, alkoxy group, aryl group, aryloxy group, heterocyclic group, halogen atom, cyano group, hydroxyl group, or amino group; a, b, c, and d are integers of 0 to 4; e is an integer of 0 to 5; p is 0 or 1; and q is an integer of 1 to 3. 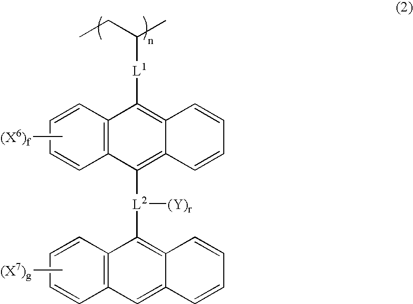
where L¹ is a bivalent organic group; L² is a bivalent aliphatic hydrocarbon group with a carbon number of 1 to 4, an aromatic group having a valence of (r+2) with a carbon number of 6 to 13, or an imino group; Y, X⁶, and X⁷ are independently univalent substituents; f is an integer of 0 to 8; g is an integer of 0 to 9; r is an integer of 0 or 1; and n is an integer of at least 1. 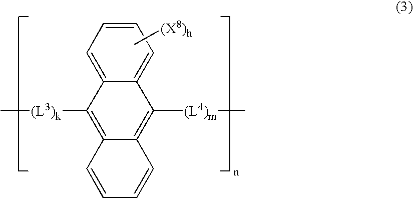
where L³ and L⁴ are bivalent organic groups; X⁸ is an alkyl group, alkoxy group, aryl group, aryloxy group, heterocyclic group, halogen atom, cyano group, hydroxyl group, or amino group; h is an integer of 0 to 8; k and m are each 0 or 1, while (k+m) is at least 1; and n is an integer of at least 1. 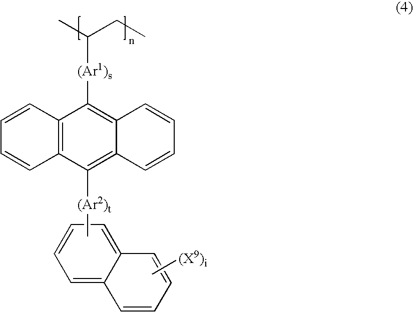
where Ar¹ and Ar² are either identical or different from each other, each representing a substituted or unsubstituted phenylene group or substituted or unsubstituted naphthylene group; X⁹ is an alkyl group, alkoxy group, aryl group, aryloxy group, heterocyclic group, halogen atom, cyano group, hydroxyl group, or amino group; s is 1 or 2; t is 0 or 1; i is an integer of 0 to 7; and n is an integer of at least 1.

Preferably, in the first organic EL device, the hole-transferring compound contained in the luminescent layer has a triphenylamine structure. In this case, the carrier balance improving effect in the luminescent layer can be obtained at a higher level, whereby an organic EL device having a longer life can be realized.

Preferably, in the first organic EL device, the luminescent layer has a modified part containing a hole-blocking compound having an ionization potential of at least 5.5 eV near a surface on the side closer to an electron injection electrode in the pair of electrodes. This makes it possible to further improve the luminous efficiency and life. The “hole-blocking compound” in the present invention refers to a compound capable of blocking holes. The inventors presume that effects obtained by the foregoing configuration are as follows but are not limited thereto.

Namely, it seems that providing the modified part near the surface of the luminescent layer on the side closer to the electron injection electrode yields an energy barrier in the vicinity of the modified part, so that the modified part functions as a blocking layer against holes, thereby sufficiently restraining holes from migrating from the luminescent layer toward the electron-injecting electrode layer by way of the modified part, while keeping a favorable carrier balance between holes and electrons in a main region where they recombine with each other in the luminescent layer. As a result, holes seem to accumulate in the vicinity of the modified part in the luminescent layer, thereby lowering the electron injection barrier (energy barrier necessary for injecting an electron into the luminescent layer) in the vicinity of the modified part. These seem to make it possible to attain an injection balance between electrons and holes in the luminescent layer, so that the probability of holes and electrons recombining with each other rises, whereby an organic EL device having a higher level of luminous efficiency and life can be obtained.

The polymer luminescent layer is usually constructed so as to contain a nonpolar material, and thus tends to exhibit an insufficient adhesion to an electron injection electrode which is a very thin film constituted by an inorganic compound or the like. The modified region is constructed so as to contain a polar polymer, whereby the surface of the luminescent layer on the modified part side can adhere to the electron injection electrode more uniformly, which makes it easier to achieve a high luminous efficiency and a long life.

When the electron injection electrode is constituted by a metal, an alloy, or their mixture, the device is likely to deteriorate because of oxidation deterioration, diffusion of dissociated ions to the hole injection electrode, and the like. The modified part can stably hold such a metal or metal compound, and thus can realize more stable driving of the device.

When a luminescent layer having no modified part and an electron injection layer come into direct contact with each other, an excited state may be deactivated because of energy transfer. However, providing the modified region can suppress such deactivation.

Here, “near the surface” of the luminescent layer refers to a volume region at most extending from the surface of the luminescent layer to a center part in the thickness direction of the luminescent layer. The “modified part containing a hole-blocking compound having an ionization potential of at least 5.5 eV” refers to a layer part where a hole-blocking compound having an ionization potential of at least 5.5 eV and a part or the whole of the material constituting the luminescent layer excluding the modified part coexist in the thickness direction of the luminescent layer, whereas the layer part where the modified part containing a hole-blocking compound having an ionization potential of at least 5.5 eV does not exist does not fall under the modified region.

The modified region of the luminescent layer can favorably be formed by applying a solution containing a hole-blocking compound having an ionization potential of at least 5.5 eV. Thus employing a coating method as a method of modifying the organic EL device near the luminescent layer surface seems to provide the modified region with a concentration gradient. More specifically, it is deemed that the concentration of the hole-blocking compound having an ionization potential of at least 5.5 eV becomes higher on the electron-injecting electrode layer side in the modified part, whereas the concentration of vinyl polymer and hole-transferring compound becomes higher toward the hole-injecting electrode layer in the modified part. It is presumed that such a concentration gradient allows the modified part to have a certain extent of large thickness area, and thus can effectively accumulate holes as a hierarchical blocking layer, thereby being able to effectively contribute to recombining the holes and electrons in the luminescent layer.

Though a technique of providing a hole-blocking layer between the luminescent layer and electron injection electrode has been known in conventional organic EL devices, effects similar to those obtained by the modified part in the first organic EL device cannot be obtained in this case. Namely, the constituent material of the hole-blocking layer differs from that of the luminescent layer in the conventional organic EL devices.

The hole-blocking compound used in the first organic EL device is preferably a polymer compound or organic metal compound having a bandgap of at least 4.0 eV. Using such a hole-blocking compound can effectively achieve further improvement in luminous efficiency and life.

In another aspect, the present invention provides a method of manufacturing an organic EL device comprising a pair of electrodes disposed so as to oppose each other and a luminescent layer, disposed between the electrodes, containing a polymer having an anthracene structure and a hole-transferring compound having a glass transition temperature of at least 70° C., the method (hereinafter referred to as “first manufacturing method”) comprising the step of forming the luminescent layer by a coating method using a coating liquid containing the polymer and hole-transferring compound.

The first manufacturing method can yield the first organic EL device easily and reliably.

Preferably, the first manufacturing method further comprises the step of annealing the luminescent layer formed by the coating method. Annealing the luminescent layer can further elongate the life of the resulting organic EL device.

In still another aspect, the present invention provides an organic EL display (hereinafter referred to as “first organic EL display”) comprising a display part having a plurality of organic EL devices arranged therein, each organic EL device comprising a pair of electrodes disposed so as to oppose each other and a luminescent layer, disposed between the electrodes, containing a polymer having an anthracene structure and a hole-transferring compound having a glass transition temperature of at least 70° C.; a power supply part, electrically connected to each of the pair of electrodes, for supplying a voltage or current to the electrodes; and a switching part for turning on/off the organic EL devices.

Thus arranging the first organic EL devices in the display part and causing the power supply part and switching part to drive the display part can realize an organic EL display which is excellent in luminance and color displaying functions while having a high heat resistance and a long life.

In still another aspect, the present invention provides an organic EL device (hereinafter referred to as “second organic EL device”) comprising a hole injection electrode and an electron injection electrode disposed so as to oppose each other; a luminescent layer, disposed between the hole injection electrode and electron injection electrode, containing a polymer having an anthracene structure and a modified part, disposed near a surface on the side closer to the electron injection electrode, containing a hole-blocking compound having a bandgap of at least 4.0 eV; and an electron-blocking layer, disposed between the hole injection electrode and luminescent layer, containing a hole-transferring compound having an electron affinity of 3.0 eV or less.

The above-mentioned second organic EL device is achieved according to the following findings by the inventors. Namely, in the conventional organic EL devices using a non-π-conjugated polymer, the injection barrier from both electrodes to the luminescent layer is so large that many carriers drop out without getting involved in carrier recombination, while the carrier mobility in the luminescent layer greatly differs between a hole and an electron, so that their equilibrium (carrier balance) is likely to be lost. By contrast, the second organic EL device causes the luminescent layer to contain the vinyl polymer having an anthracene structure, modifies the luminescent layer in the vicinity of the surface on the electron injection electrode side with the hole-blocking compound having a specific bandgap, and provides the electron-blocking layer containing a specific hole-transferring compound between the hole injection electrode and luminescent layer, so as to make it possible to improve the luminous efficiency and keep device characteristics such as luminance and luminous efficiency at a high level for a long period, whereby a long-life organic EL device can effectively be realized.

Though the reason why the second organic EL device achieves the effects mentioned above is not definitely clear, the inventors presume as follows.

Namely, it seems that, since the luminescent layer contains a polymer having an anthracene structure, the carrier mobility (each of the hole mobility and electron mobility) is enhanced in the luminescent layer of the second organic EL device. Forming the modified part containing a hole-blocking compound having a bandgap of at least 4.0 eV near the surface of the luminescent layer on the electron injection electrode side and providing the electron-blocking layer containing the specific hole-transferring compound between the luminescent layer and hole injection electrode seems to lower the injection barrier against the electron and hole from the electrodes to the luminescent layer (the energy barrier required for injecting the electron or hole into the luminescent layer) decreases, and the carrier balance between the electrons and holes injected in the luminescent layer is held favorably. From these reasons, the inventors presume that the efficiency in recombining the electrons and holes improves in the luminescent layer, whereby device characteristics such as luminance and luminous efficiency can be kept at a high level for a long period.

Also, since the luminescent layer contains a polymer having an anthracene structure, it seems that characteristics such as voltage endurance, heat resistance, and oxidation resistance are fully enhanced, whereby the carrier balance improving effect achieved by using both of the two ingredients mentioned above can be obtained even when the device is driven for a long period or repeatedly.

The second organic EL device is preferred in the case where each of the luminescent layer and electron-blocking layer is formed by a coating method. Heating (annealing) a luminescent layer in the process of manufacturing an organic EL device is effective in achieving a longer life. However, the luminescent layers of the conventional organic EL devices may fail to emit light or shorten their life upon annealing, since they do not always have a favorable heat resistance. By contrast, the second organic EL device can attain a high level of life elongating effect by annealing, since the luminescent layer has a sufficient heat resistance as mentioned above.

Here, “near the surface” of the luminescent layer refers to a volume region at most extending from the surface of the luminescent layer to a center part in the thickness direction of the luminescent layer. The “modified part containing a hole-blocking compound having a bandgap of at least 4.0 eV” refers to a layer part where a hole-blocking compound having a bandgap of at least 4.0 eV and a part or the whole of the material constituting the luminescent layer excluding the modified part coexist in the thickness direction of the luminescent layer, whereas the layer part where the modified part containing a hole-blocking compound having a bandgap of at least 4.0 eV does not exist does not fall under the modified region.

The modified region of the luminescent layer can favorably be formed by applying a solution containing a hole-blocking compound having a bandgap of at least 4.0 eV. Thus employing a coating method as a method of modifying the organic EL device near the luminescent layer surface seems to provide the modified region with a concentration gradient. More specifically, it is deemed that the concentration of the hole-blocking compound having a bandgap of at least 4.0 eV becomes higher on the electron-injecting electrode layer side in the modified part, whereas the concentration of vinyl polymer and low-molecular hole-transferring compound becomes higher toward the hole-injecting electrode layer in the modified part. It is presumed that such a concentration gradient allows the modified part to have a certain extent of large thickness area, and thus can effectively accumulate holes as a hierarchical blocking layer, thereby being able to effectively contribute to recombining the holes and electrons in the luminescent layer.

Though a technique of providing a hole-blocking layer between the luminescent layer and electron injection electrode has been known in conventional organic EL devices, effects similar to those obtained by the modified part in the second organic EL device cannot be obtained in this case. Namely, since a hole-blocking layer having a thickness (typically 10 to 50 nm) necessary for blocking holes is formed by vapor deposition using an electron-transferring material, different from the constituent material of the luminescent layer, having a mobility lower than that of the hole-transferring material, the driving voltage is likely to become higher in the conventional organic EL devices. Also, since a clear interface exists between the luminescent layer and electron-transferring layer, they are easier to separate from each other at the interface, and thus cannot be driven stably.

Preferably, the luminescent layer in the second organic EL device is obtained by forming a coating film by a coating method using a coating liquid containing the polymer and applying a coating liquid containing a hole-blocking compound onto a surface of the coating film on the side closer to the electron injection electrode, so as to form the modified part.

Preferably, in the second organic EL device, the modified part in the luminescent layer is formed in a region distanced by 0.1 to 10 nm from the surface of the luminescent layer on the side closer to the electron injection electrode in the depth direction of the luminescent layer.

Preferably, in the second organic EL device, the above-mentioned polymer contained in the luminescent layer contains at least one species selected from the structure units represented by the following general formulas (1) to (4). Using such a polymer can effectively realize a long-life organic EL device which can keep device characteristics such as luminance and luminous efficiency at a high level for a long period. 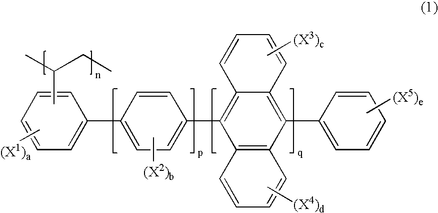
where X¹, X², X¹, X⁴, and X⁵ are either identical or different from each other, each representing an alkyl group, alkoxy group, aryl group, aryloxy group, heterocyclic group, halogen atom, cyano group, hydroxyl group, or amino group; a, b, c, and d are integers of 0 to 4; e is an integer of 0 to 5; p is 0 or 1; and q is an integer of 1 to 3. 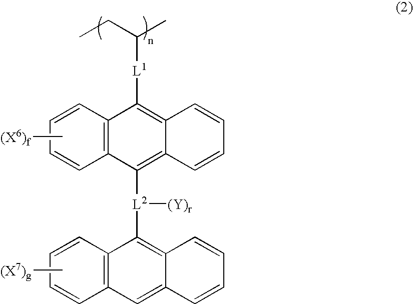
where L¹ is a bivalent organic group; L² is a bivalent aliphatic hydrocarbon group with a carbon number of 1 to 4, an aromatic group having a valence of (r+2) with a carbon number of 6 to 13, or an imino group; Y, X⁶, and X⁷ are independently univalent substituents; f is an integer of 0 to 8; g is an integer of 0 to 9; r is an integer of 0 or 1; and n is an integer of at least 1. 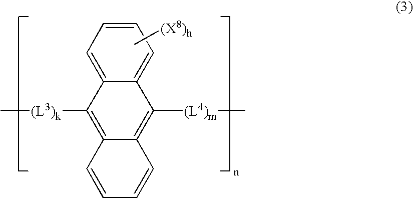
where L³ and L⁴ are bivalent organic groups; X⁸ is an alkyl group, alkoxy group, aryl group, aryloxy group, heterocyclic group, halogen atom, cyano group, hydroxyl group, or amino group; h is an integer of 0 to 8; k and m are each 0 or 1, while (k+m) is at least 1; and n is an integer of at least 1. 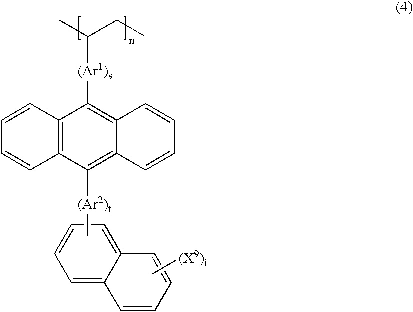
where Ar¹ and Ar² are either identical or different from each other, each representing a substituted or unsubstituted phenylene group or substituted or unsubstituted naphthylene group; X⁹ is an alkyl group, alkoxy group, aryl group, aryloxy group, heterocyclic group, halogen atom, cyano group, hydroxyl group, or amino group; s is 1 or 2; t is 0 or 1; i is an integer of 0 to 7; and n is an integer of at least 1.

Preferably, in the second organic EL device, the modified part in the luminescent layer contains a nonluminous polymer compound and/or organic metal compound having an ionization potential of at least 5.5 eV. On the other hand, it will be preferred if the electron-blocking layer contains a polymer compound having a triphenylamine structure with an electron affinity of 3.0 eV or less. This can effectively achieve the hole-blocking effect in the vicinity of the surface of the luminescent layer on the electron injection electrode side, the electron-blocking effect in the electron-blocking layer, and the carrier balance improving effect in the luminescent layer.

Preferably, in the second organic EL device, the luminescent layer further contains a hole-transferring compound having a glass transition temperature of at least 70° C. The luminescent layer containing such a hole-transferring compound can further improve device characteristics such as luminance and luminous efficiency, and keep these characteristics for a longer period. The reason why the luminescent layer of the second organic EL device containing the hole-transferring compound achieves such effects is not definitely clear, but the inventors presume as follows.

Namely, it seems that the hole-transferring compound is held within the polymer having the anthracene structure in the luminescent layer, so that each carrier mobility is enhanced without increasing the difference between the hole mobility and electron mobility. Therefore, it is deemed that the carrier balance can be kept in a favorable state so that the holes and electrons efficiently recombine with each other, whereby not only improvements in device characteristics such as luminance and luminous efficiency, but also a longer life can be achieved at a high level.

Also, since the luminescent layer contains a polymer having an anthracene structure and the hole-transferring compound having a glass transition temperature of at least 70° C., it seems that characteristics such as voltage endurance, heat resistance, and oxidation resistance are fully enhanced, whereby the carrier balance improving effect achieved by using both of the two ingredients mentioned above can be obtained even when the device is driven for a long period or repeatedly.

In the manufacturing process of an organic EL device, heating (annealing) the luminescent layer formed by the coating method is effective in elongating the life. However, the luminescent layers of the conventional organic EL devices do not always have a favorable heat resistance, and thus may shorten their life after being annealed. By contrast, the above-mentioned second organic EL device can attain a high level of life improving effect by the annealing, since the luminescent layer has a sufficient heat resistance as mentioned above.

In still another aspect, the present invention provides a method of manufacturing an organic EL device comprising a hole injection electrode and an electron injection electrode disposed so as to oppose each other; a luminescent layer, disposed between the hole injection electrode and electron injection electrode, containing a polymer having an anthracene structure and a modified part, disposed near a surface on the side closer to the electron injection electrode, containing a hole-blocking compound having a bandgap of at least 4.0 eV; and an electron-blocking layer, disposed between the hole injection electrode and luminescent layer, containing a hole-transferring compound having an electron affinity of 3.0 eV or less; the method (hereinafter referred to as “second manufacturing method”) comprising the step of forming a coating film by a coating method using a coating liquid containing the polymer, and further applying a coating liquid containing the hole-blocking compound onto a surface of the coating film on the side closer to the electron injection electrode, so as to form the modified part, thereby providing the luminescent layer.

The second manufacturing method can yield the second organic EL device easily and reliably.

In still another aspect, the present invention provides an organic EL display (hereinafter referred to as “second organic EL display”) comprising a display part having a plurality of organic EL devices arranged therein, each organic EL device comprising a hole injection electrode and an electron injection electrode disposed so as to oppose each other, a luminescent layer, disposed between the hole injection electrode and electron injection electrode, containing a polymer having an anthracene structure and a modified part, disposed near a surface on the side closer to the electron injection electrode, containing a hole-blocking compound having a bandgap of at least 4.0 eV, and an electron-blocking layer, disposed between the hole injection electrode and luminescent layer, containing a hole-transferring compound having an electron affinity of 3.0 eV or less; a power supply part, electrically connected to each of the pair of electrodes, for supplying a voltage or current to the electrodes; and a switching part for turning on/off the organic EL devices.

Thus arranging the second organic EL devices in the display part and causing the power supply part and switching part to drive the display part can realize an organic EL display which is excellent in luminance and color displaying functions while having a high heat resistance and a long life.

### BRIEF DESCRIPTION OF THE DRAWINGS

FIG. 1 is a sectional view of a major part schematically showing a preferred embodiment of the first organic EL device;

FIG. 2 is a sectional view schematically showing the vicinity of the luminescent layer 20A in the organic EL device 1A;

FIG. 3 is a block diagram schematically showing a preferred embodiment of the first EL display;

FIG. 4 is a sectional view of a major part schematically showing a preferred embodiment of the second organic EL device;

FIG. 5 is a sectional view schematically showing the vicinity of the luminescent layer 20B in the organic EL device 1B; and

FIG. 6 is a block diagram schematically showing a preferred embodiment of the first EL display.

### DESCRIPTION OF THE PREFERRED EMBODIMENTS

In the following, preferred embodiments of the present invention will be explained in detail with reference to the drawings. In the drawings, constituents identical to each other will be referred to with numerals identical to each other without repeating their overlapping descriptions. Positional relationships such as upper, lower, left, and right will be based on those shown in the drawings unless otherwise specified. Ratios of dimensions in the drawings are not limited to those depicted.

To begin with, the first organic EL device, first manufacturing method, and first organic EL display will be explained.

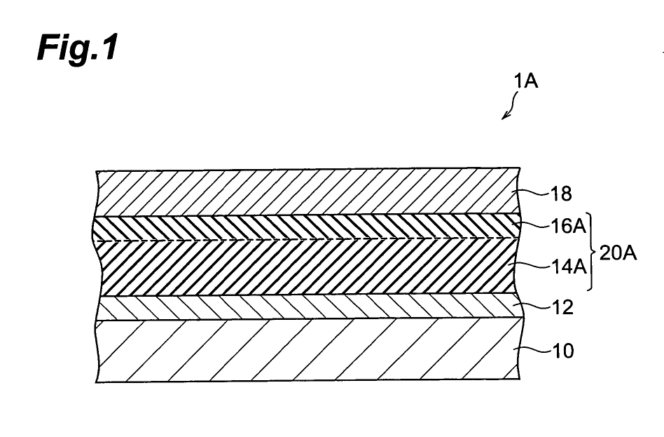

FIG. 1 is a schematic sectional view showing a preferred embodiment of the first organic EL device. The organic EL device 1A shown in FIG. 1 comprises a substrate 10, a first electrode layer (hole-injecting electrode layer) 12 formed on one side of the substrate 10, a luminescent layer 20A formed on the hole-injecting electrode layer 12, and a second electrode layer (electron-injecting electrode layer) 18 formed on the luminescent layer 20A. As will be explained later, the luminescent layer 20A is an organic layer containing a vinyl polymer including an anthracene structure and a hole-transferring compound having a glass transition temperature of at least 70° C. The luminescent layer 20A is constituted by a modified part 16A, formed near the surface on the electron-injecting electrode layer 18 side, containing a hole-blocking compound having an ionization potential of at least 5.5 eV; and the other part 14A.

Substrate

Examples of the substrate 10 include amorphous substrates (e.g., glass and silica) and crystal substrates (e.g., Si, GaAs, ZnSe, ZnS, GaP, and InP), whereas substrates having a crystalline, amorphous, or metal buffer layer formed on these crystal substrates can also be used. Mo, Al, Pt, Ir, Au, Pd, and the like can be used as a metal substrate. Resin film substrates (e.g., polyethylene terephthalate) can also be used.

When the substrate 10 is on the light exit side, a transparent substrate such as glass or silica is preferably used. In particular, a transparent glass substrate which is inexpensive is preferably used. The transparent substrate may be provided with a color filter film, a color conversion film containing a fluorescent material, a dielectric reflective film, and the like in order to adjust luminescent colors.

Hole-Injecting Electrode Layer

The material used in the hole-injecting electrode (anode) layer 12 is preferably one which can efficiently inject holes into the luminescent layer, and is preferably a material having a work function of 4.5 eV to 5.5 eV. Specifically, it is mainly composed of any of transparent conductive films of indium tin oxide (ITO), indium zinc oxide (IZO), indium oxide (In₂O₃), tin oxide (SnO₂), and zinc oxide (ZnO).

These oxides may more or less deviate from their stoichiometric compositions. The mixing ratio of SnO₂ to In₂O₃ in ITO is preferably 1 to 20 mass %, more preferably 5 to 12 mass %. The mixing ratio of ZnO to In₂O₃ in IZO is typically on the order of 12 to 32 mass %. For adjusting the work function, the hole-injecting electrode layer 12 may contain silica (SiO₂). The SiO₂ content is preferably on the order of 0.5 to 10 mol % with respect to ITO. ITO containing SiO₂ tends to increase its work function.

Without being restricted to the hole-injecting electrode layer, the electrode layer on the light exit side preferably has a transmittance of at least 50%, more preferably at least 80%, further preferably at least 90% within the wavelength range of 400 to 700 nm, which is an emission wavelength region of an organic EL device, at respective wavelengths of colors R, G, and B in particular. When the light transmittance is less than 50%, the emission from the luminescent layer itself tends to attenuate, whereby a luminance required for a light-emitting device is harder to attain.

Preferably, the thickness of the hole-injecting electrode layer 12 is determined in view of the above-mentioned light transmittance, since this layer becomes the electrode layer on the light exit side. When a transparent conductive film made of an oxide is used, for example, its thickness is preferably 50 to 500 nm, more preferably 50 to 300 nm. When the thickness of the hole-injecting electrode layer 12 exceeds 500 nm, the light transmittance is less likely to become sufficient, while the hole-injecting electrode layer 12 tends to peel off from the substrate 10. The light transmittance improves as the film thickness decreases. When the film thickness is less than 50 nm, however, the efficiency of injecting holes into the luminescent layer 20A is more likely to decrease, while the strength of the film tends to lower.

Electron-Injecting Electrode Layer

The material used in the electron-injecting electrode (cathode) layer 18 is not restricted in particular, since it is not required to have a relatively low work function thanks to the effects of a modified part 16A in the luminescent layer 20A which will be explained later. Therefore, alkali metals such as Li, Na, K, and Cs, alkali earth metals such as Mg, Ca, Sr, and Ba; alkali halides such as LiF and CsI, oxides such as Li₂O, and metals such as La, Ce, Sn, Zn, and Zr having characteristics similar to alkali metals or alkali earth metals having a relatively low work function; metals having a relatively high work function such as Al, Ag, In, Ti, Cu, Au, Mo, W, Pt, Pd, and Ni, their alloys, and alloys formed by these metals and other metals can be used. They may be used either singly or in combinations of two or more species.

Among the materials mentioned above, LiF is preferably used in the electron-injecting electrode layer 18 from the viewpoint of effectively exhibiting functions of the luminescent layer 20A which will be explained later. When employing LiF in the electron-injecting electrode layer, the conventional organic EL devices using a polymer compound in the luminescent layer have been hard to obtain a sufficient luminous efficiency and life. However, by providing the luminescent layer 20A with the modified part 16A, this embodiment is apt to achieve an excellent luminous efficiency and life even when LiF is used in the electron-injecting electrode layer 18.

When the luminescent layer 20A does not have the modified part 16A, it will be preferred if a material having a relatively low work function is used among the above-mentioned materials.

Though the thickness of the electron-injecting electrode layer 18 is not restricted in particular as long as electrons can be injected into the luminescent layer 20A, it is preferably 0.1 to 100 nm, more preferably 1.0 to 50 nm, when an alkali metal or alkali earth metal is used. When an alkali halide or an oxide such as Li₂O is used, the film thickness is preferably as small as possible from the viewpoint of the capability to inject electrons into the luminescent layer 20A. Specifically, the thickness is preferably 10 nm or less, more preferably 1 nm or less.

Luminescent Layer

As mentioned above, the luminescent layer 20A is an organic layer containing a vinyl polymer having an anthracene structure and a hole-transferring compound having a glass transition temperature of at least 70° C. The luminescent layer 20A is constituted by the modified part 16A, formed near the surface on the electron-injecting electrode layer 18 side, containing a hole-blocking compound having an ionization potential of at least 5.5 eV; and the other part 14A.

The vinyl polymer used in the luminescent layer 20A is not restricted in particular as long as it has a side chain group containing the anthracene structure. The side chain group may have a benzene structure, a naphthalene structure, a diphenylnaphthacene structure, a pyrene structure, a phenanthrene structure, a phenanthroline structure, a fluoranthene structure, a fluorene structure, or a structure combining two or more species of these structures in addition to the anthracene structure. The vinyl polymer may have a side chain group containing no anthracene structure in addition to the side chain group containing the anthracene structure. Examples of the side chain group having no anthracene structure include those containing a benzene structure, a naphthalene structure, a diphenylnaphthacene structure, a pyrene structure, a phenanthrene structure, a phenanthroline structure, a fluoranthene structure, a fluorene structure, or a structure combining two or more species of these structures in addition to the anthracene structure.

The vinyl polymer having a side chain group containing an anthracene structure can be obtained by polymerizing a polymerizable monomer containing a vinyl monomer in which a vinyl group is introduced into anthracene or an anthracene derivative. Using Suzuki reaction, Grignard reaction, or the like, the aimed compound can be obtained without affecting the vinyl group when introducing the vinyl group. The polymerizing method is not restricted in particular, whereby polymerization can easily be achieved by radical polymerization, cationic polymerization, anionic polymerization, and the like.

Preferred as the vinyl polymer having the anthracene structure is a vinyl polymer including at least one species selected from the structure units represented by the following general formulas (1) to (4).

First, the structure unit represented by the following general formula (1) will be explained.

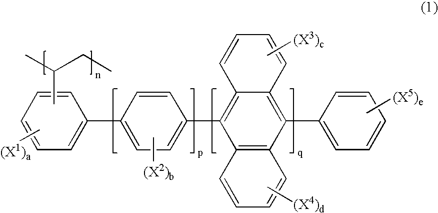

In the above-mentioned general formula (1), X¹, X², X³, X⁴, and X⁵ may be either identical or different from each other, each representing an alkyl group, alkoxy group, aryl group, aryloxy group, heterocyclic group, halogen atom, cyano group, hydroxyl group, or amino group, whereas these substituents may combine with each other to form a ring. On the other hand, a, b, c, and d are integers of 0 to 4; e is an integer of 0 to 5; p is 0 or 1; and q is an integer of 1 to 3.

When any of X¹ to X⁵ is an alkyl group, the alkyl group may be linear or branched. The alkyl group is preferably unsubstituted but may have a substituent. The carbon number in the alkyl group is preferably 1 to 30. Preferred examples of the alkyl group include methyl, ethyl, n-propyl, isopropyl, n-butyl, isobutyl, s-butyl, t-butyl, and pentyl groups.

When any of X¹ to X⁵ is an alkoxy group, the alkyl group constituting the alkoxy group may be linear or branched. The alkoxy group is preferably unsubstituted but may have a substituent. The carbon number in the alkoxy group is preferably 1 to 30. Preferred examples of the alkoxy group include methoxy, ethoxy, n-propoxy, isopropoxy, n-butoxy, isobutoxy, s-butoxy, and t-butoxy group.

When any of X¹ to X⁵ is an aryl group, the aryl group may be either substituted or unsubstituted, whereas the total carbon number in the aryl group is preferably 6 to 20. Preferred examples of the aryl group include phenyl, o-tolyl, m-tolyl, p-tolyl, and biphenylyl groups.

When any of X¹ to X⁵ is an aryloxy group, the aryl group constituting the aryloxy group may be either substituted or unsubstituted, whereas the total carbon number in the aryloxy group is preferably 6 to 20. Preferred examples of the aryloxy group include phenoxy, o-tolyloxy, m-tolyloxy, and p-tolyloxy groups.

When any of X¹ to X⁵ is a heterocyclic group, the heterocyclic group is preferably a 5- or 6-membered ring group. The heterocyclic group may have a condensed ring or a substituent. The heterocyclic group may have either an aromaticity or not. Preferred examples of the heterocyclic group include pyrrolyl, pyridyl, quinolyl, thienyl, and furyl groups.

When any of X¹ to X⁵ is a halogen atom, examples of the halogen atom include fluorine, chlorine, bromine, and iodine.

When any of X¹ to X⁵ is an amino group, the amino group may be either substituted or unsubstituted. For example, it may have the above-mentioned alkyl or aryl group. The total carbon number in the amino group is preferably 0 to 20. Preferred examples of the amino group include amino group in the narrow sense (—NH₂) and methylamino, ethylamino, phenylamino, dimethylamino, and diphenylamino groups.

By appropriately choosing the numbers of benzene rings and anthracene rings in its corresponding vinyl monomer and species and numbers of X¹ to X⁵, the vinyl polymer having the structure unit represented by general formula (1) can adjust the glass transition temperature of the resulting polymer, so as to improve its heat resistance, while improving the fluorescent quantum efficiency and bipolarity, whereby the luminous efficiency and life of the organic EL device can further be improved.

Specifically, preferred examples of the structure unit represented by the above-mentioned general formula (1) include structure units (1-1) to (1-32) shown in the following Tables 1 to 4. In each of the formulas representing the structure units, n is an integer of 1 or greater. The polymer in accordance with the present invention may be either a homopolymer made of one species of the following structure units or a copolymer made of two or more species of the following structure units, and may further contain structure units other than those represented by the above-mentioned general formula (1). When the polymer is a copolymer, it may be either a block copolymer or random copolymer.

TABLE 1

| | | | |
|---|---|---|---|
| No. | 1-1 | 1-2 | 1-3 |
| Structure unit | 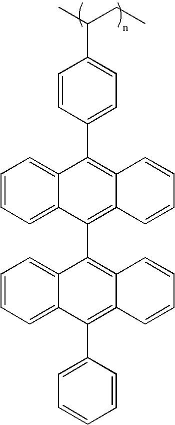 | 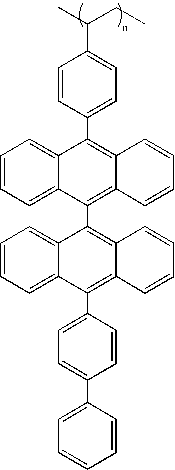 | 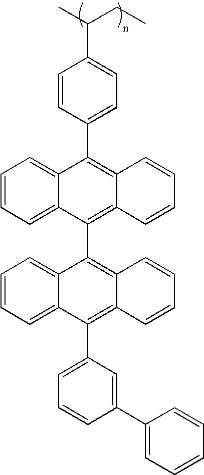 |
| No. | 1-4 | 1-5 | 1-6 |
| Structure unit | 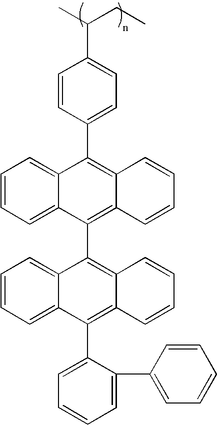 | 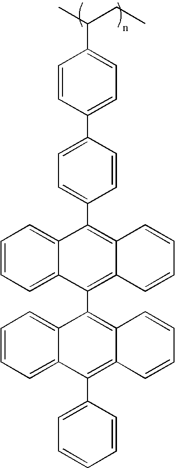 | 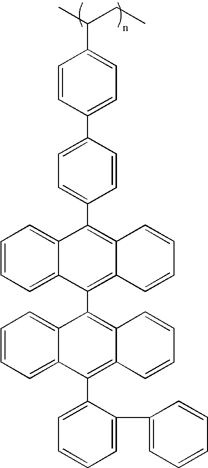 |
| No. | 1-7 | 1-8 | 1-9 |
| Structure unit | 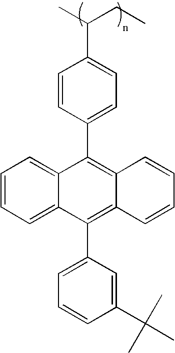 | 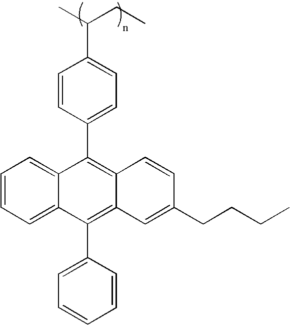 | 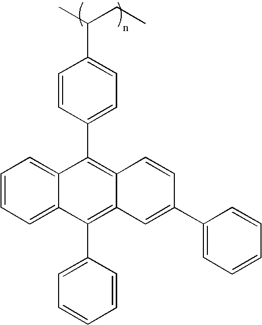 |

TABLE 2

| | | | |
|---|---|---|---|
| No. | 1-10 | 1-11 | 1-12 |
| Structure unit | 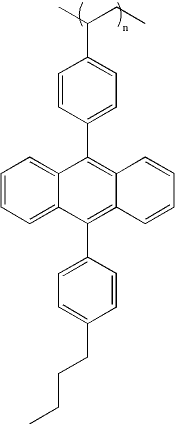 | 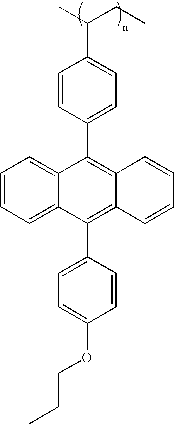 | 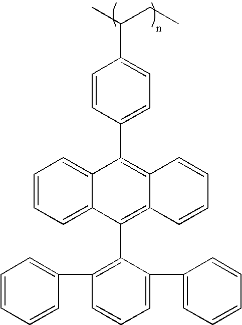 |
| No. | 1-13 | 1-14 | 1-15 |
| Structure unit | 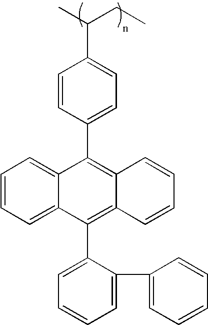 | 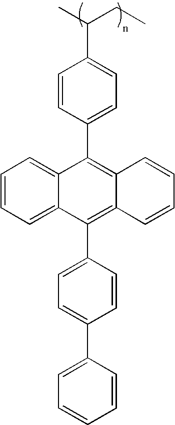 | 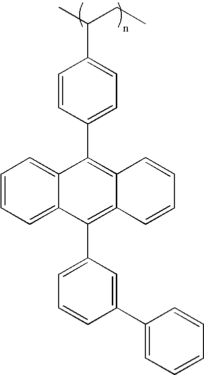 |
| No. | 1-16 | 1-17 | 1-18 |
| Structure unit | 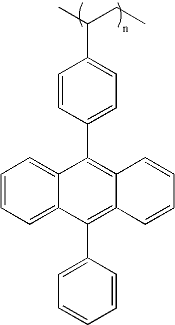 | 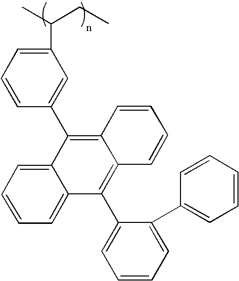 | 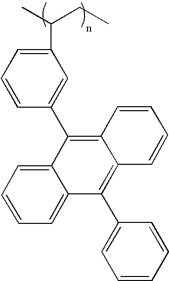 |

TABLE 3

| | | | |
|---|---|---|---|
| No. | 1-19 | 1-20 | 1-21 |
| Structure unit | 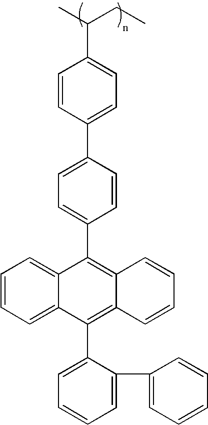 | 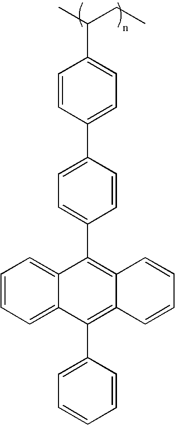 | 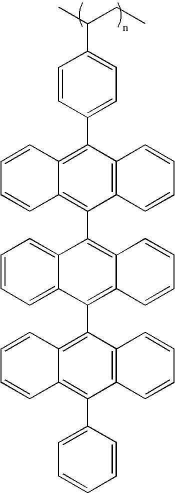 |
| No. | 1-22 | 1-23 | 1-24 |
| Structure unit | 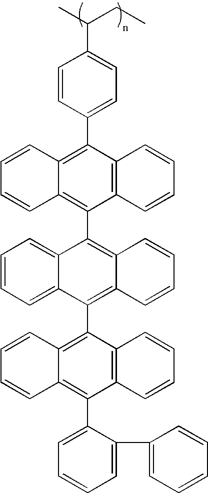 | 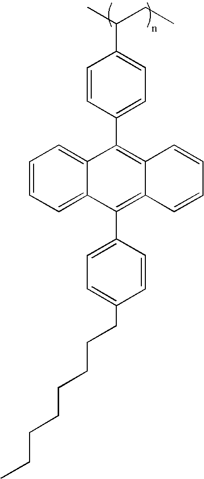 | 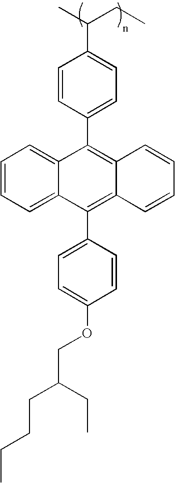 |
| No. | 1-25 | 1-26 | 1-27 |
| Structure unit | 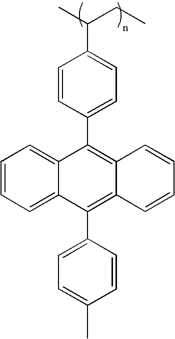 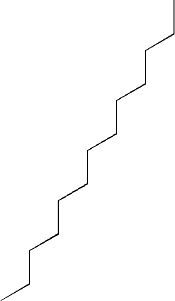 | 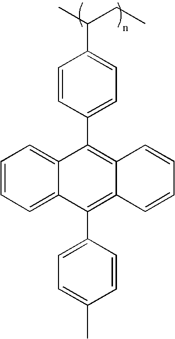 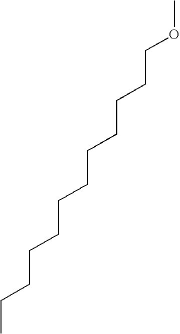 | 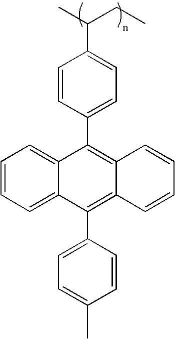 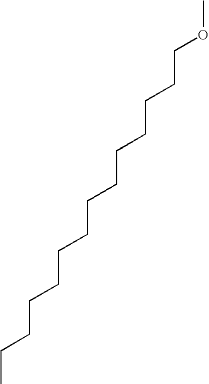 |

TABLE 4

| | | | |
|---|---|---|---|
| No. | 1-28 | 1-29 | 1-30 |
| Structure unit | 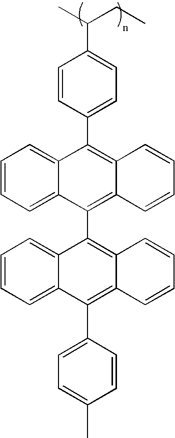 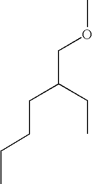 | 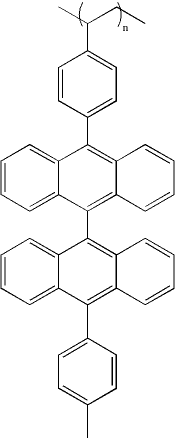 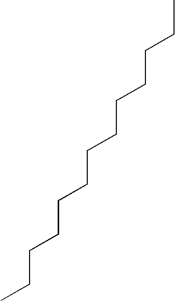 | 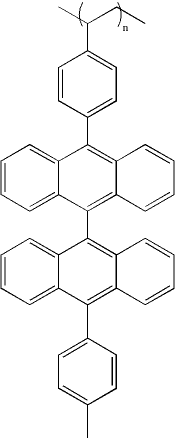 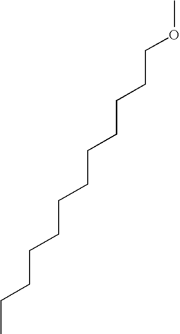 |
| No. | 1-31 | 1-32 | |
| Structure unit | 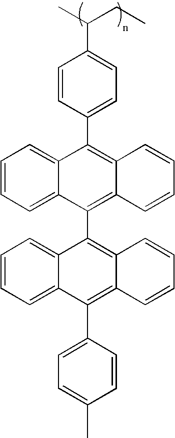 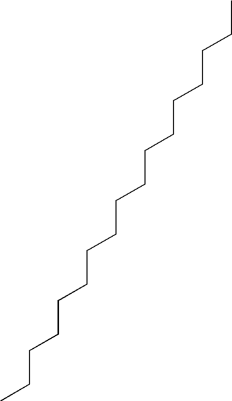 | 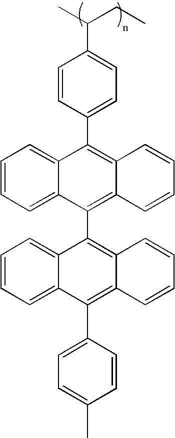 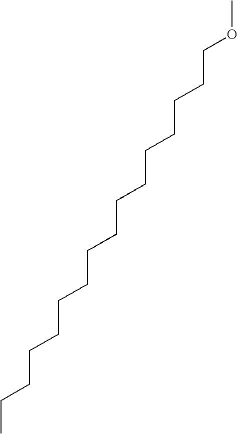 | |

The polymer having the structure unit represented by general formula (1) can be obtained by homopolymerization of one species of vinyl monomer corresponding to its structure unit or copolymerization of two or more species of vinyl monomer. Preferred examples of the vinyl monomer include compounds represented by the following general formulas (1-a), (1-b), and (1-c):

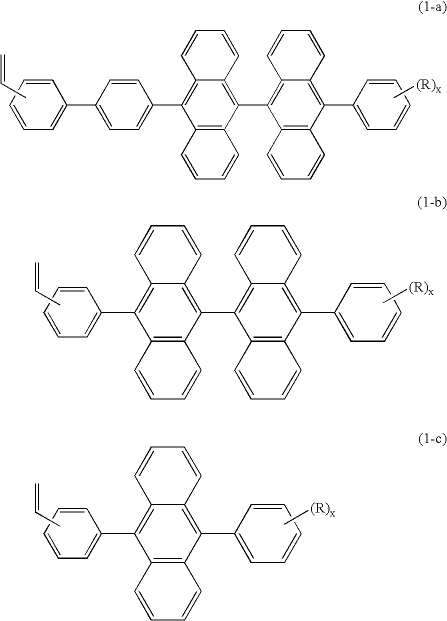

In the above-mentioned general formulas (1-a), (1-b), and (1-c), R is an alkyl group having a carbon number of 1 to 30 or an alkoxy group having a carbon number of 1 to 30, preferably an alkyl group having a carbon number of 1 to 20 or an alkoxy group having a carbon number of 1 to 20, more preferably an alkyl group having a carbon number of 1 to 12 or an alkoxy group having a carbon number of 1 to 12. The alkyl or alkoxy group represented by R may be either linear or branched. Preferred examples of the alkyl group include n-butyl, t-butyl, hexyl, ethylhexyl, n-heptyl, isoheptyl, n-octyl, isooctyl, n-nonyl, isononyl, n-decyl, isodecyl, n-undecyl, isoundecyl, n-dodecyl, and isododecyl groups. Preferred examples of the alkoxy group include butyloxy, hexyloxy, ethylhexyloxy, octyloxy, dodecyloxy, hexadecyloxy, and eicosyloxy groups.

In the formulas, x is the number of substituents R, and is an integer of 1 to 5. Though the substituting position of R is not restricted in particular, a compound in which R is bound to the p-position is preferably used.

When the vinyl monomer represented by the general formula (1-a), (1-b), or (1-c) is used, the glass transition temperature of the vinyl polymer can arbitrarily be adjusted by appropriately choosing the species of alkyl group R in the vinyl monomer.

The structure unit represented by the following general formula (2) will now be explained.

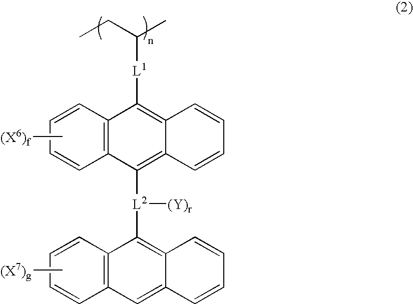

In general formula (2), L¹ is a bivalent organic group; L² is a bivalent aliphatic hydrocarbon group having a carbon number of 1 to 4, an aromatic group having a valence of (r+2) with a carbon number of 6 to 13, or an imino group; y, X⁶, and X⁷ are independently univalent substituents; f is an integer of 0 to 8; g is an integer of 0 to 9; r is an integer of 0 or 1; and n is an integer of at least 1.

L¹ is preferably a bivalent hydrocarbon group, more preferably a bivalent aromatic hydrocarbon group, further preferably a bivalent aromatic hydrocarbon group having a carbon number of 6 to 13, among bivalent organic groups.

L² is preferably an aromatic group having a valence of (p+2) with a carbon number of 6 to 13 among the bivalent groups mentioned above. When the carbon number in the aromatic group exceeds 13, the molecular structure becomes inflexible, so that the vinyl polymer is easier to crystallize, and the wavelength range of emission color shifts, thereby changing the emission color. The aromatic group may be based on either hydrocarbons or heterocycles, but is more preferably a phenylene, naphthylene, biphenylene, fluorenylene, or carbazolylene group, further preferably a phenylene or naphthylene group, a phenylene group in particular.

In the case where L² is an imino group, L² is an imino group and a bivalent group represented by —NY— when p is 0 and 1, respectively.

The structure unit represented by the above-mentioned formula (2) is excellent in molecular structure stability, since L¹ and L² are bound to the 9- and 10-positions of an anthracene skeleton, respectively.

Y is preferably a hydrocarbon group, more preferably an aliphatic or aromatic hydrocarbon group, further preferably an aliphatic or aromatic hydrocarbon group having a carbon number of 1 to 6. The aromatic hydrocarbon group is preferably a phenyl or naphthyl group, more preferably a phenyl group. In the bivalent group represented by L²-(Y)ᵣ, r is more preferably 0.

Preferably, X⁶ and X⁷ are independently any of alkyl groups, alkoxy groups, aryl groups, aryloxy groups, heterocyclic groups, halogen atoms, cyano group, hydroxyl group, and amino group, and may be combined together to form a ring.

When any of X⁶ and X⁷ is an alkyl group, the alkyl group may be either linear or branched. The alkyl group is preferably unsubstituted but may have a substituent. The carbon number in the alkyl group is preferably 1 to 30. Preferred examples of the alkyl group include methyl, ethyl, n-propyl, isopropyl, n-butyl, isobutyl, s-butyl, t-butyl, and pentyl groups.

When any of X⁶ and X⁷ is an alkoxy group, the alkoxy group may be either linear or branched. The alkoxy group is preferably unsubstituted but may have a substituent. The carbon number in the alkoxy group is preferably 1 to 30. Preferred examples of the alkoxy group include methoxy, ethoxy, n-propoxy, isopropoxy, n-butoxy, isobutoxy, s-butoxy, and t-butoxy groups.

When any of X⁶ and X⁷ is an aryl group, the aryl group may be either substituted or unsubstituted. The total carbon number in the aryl group is preferably 6 to 20. Preferred examples of the aryl group include phenyl, o-tolyl, m-tolyl, p-tolyl, and biphenyl groups.

When any of X⁶ and X⁷ is an aryloxy group, the aryl group constituting the aryloxy group may be either substituted or unsubstituted. The total carbon number in the aryl group is preferably 6 to 20. Preferred examples of the aryloxy group include phenoxy, o-tolyloxy, m-tolyloxy, and p-tolyloxy groups.

When any of X⁶ and X⁷ is a heterocyclic group, the heterocyclic group is preferably a 5- or 6-membered ring group. The heterocyclic group may have a condensed ring or substituent. The heterocyclic group may have an aromaticity or not. Preferred examples of the heterocyclic group include pyrrolyl, pyridyl, quinolyl, thienyl, and furyl groups.

When any of X⁶ and X⁷ is a halogen atom, examples of the halogen atom include fluorine, chlorine, bromine, and iodine.

When any of X⁶ and X⁷ is an amino group, the amino group may be either substituted or unsubstituted, and may have the above-mentioned alkyl or aryl group, for example. The total carbon number in the amino group is preferably 0 to 20. Preferred examples of the amino group include amino group in the narrow sense (—NH₂) and methylamino, ethylamino, phenylamino, dimethylamino, and diphenylamino groups.

Preferably, the structure unit represented by the above-mentioned general formula (2) is one in which at least one X⁷ is present and bound to the 10-position of the anthracene structure, i.e., the structure unit represented by the following formula (2-a):

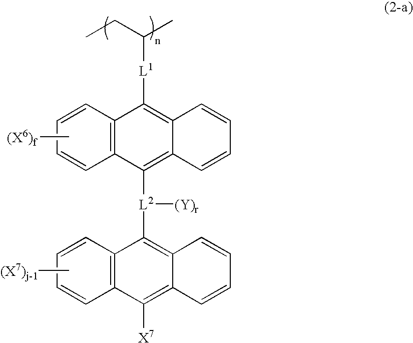

In formula (2-a), L¹ is a bivalent organic group; L² is a bivalent aliphatic hydrocarbon group with a carbon number of 1 to 4, an aromatic group having a valence of (r+2) with a carbon number of 6 to 13, or an imino group; Y, X⁶, and X⁷ are independently univalent substituents; f is an integer of 0 to 8 (more preferably 0 to 4); j is an integer of 1 to 9 (more preferably 1 to 4); r is an integer of 0 or 1; and n is an integer of at least 1. Namely, L¹, L², Y, X⁶, X⁷, f, and r in the above-mentioned formula (2-a) are synonymous with those in the above-mentioned general formula (2), respectively. X⁷ bound to the 10-position of the anthracene skeleton is preferably an aryl group, more preferably an aryl group having a carbon number of 6 to 18.

Specific preferred examples of the structure unit represented by the above-mentioned formula (2-1) include structure units (2-1) to (2-13) shown in the following Tables 5 and 6. In each of the formulas representing the structure units, n is an integer of 1 or greater. The polymer in accordance with the present invention may be either a homopolymer made of one species of the following structure units or a copolymer made of two or more species of the following structure units, and may further contain structure units other than those represented by the above-mentioned general formula (2). When the polymer is a copolymer, it may be either a block copolymer or random copolymer.

TABLE 5

| | | | |
|---|---|---|---|
| No. | 2-1 | 2-2 | 2-3 |
| Structure unit | 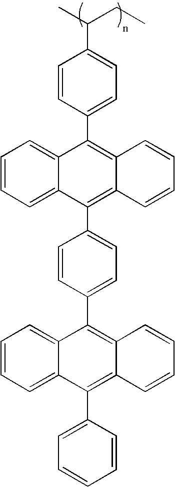 | 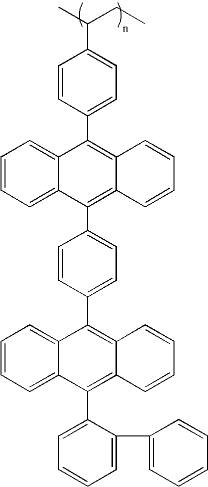 | 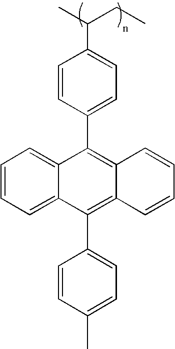 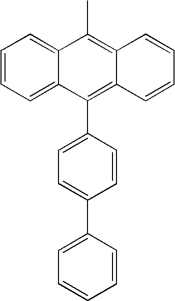 |
| No. | 2-4 | 2-5 | 2-6 |
| Structure unit | 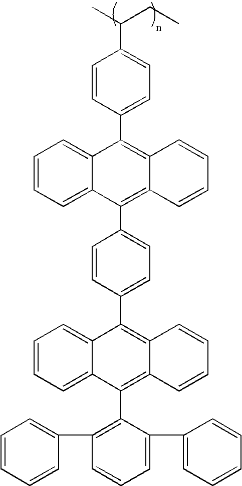 | 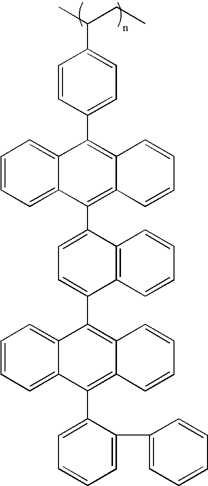 | 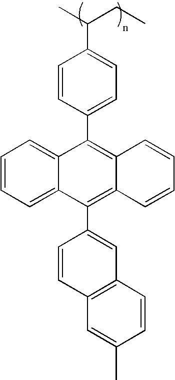 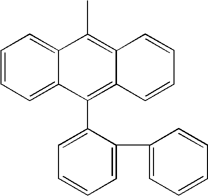 |
| No. | 2-7 | 2-8 | 2-9 |
| Structure unit | 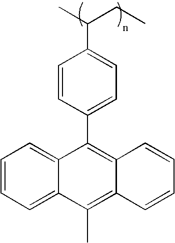 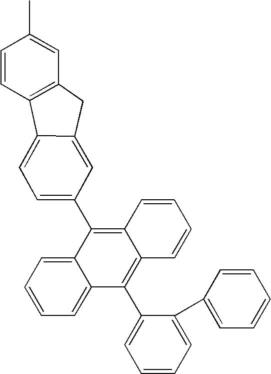 | 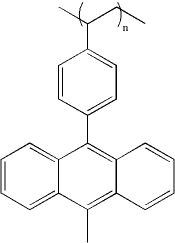 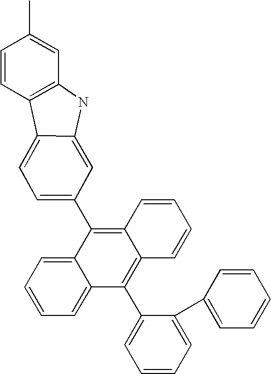 | 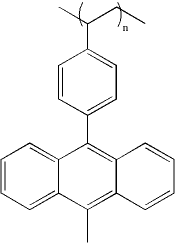 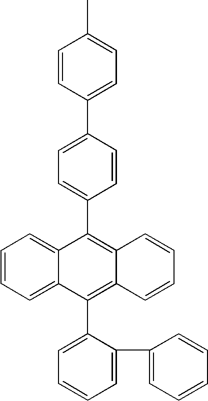 |

TABLE 6

| | | |
|---|---|---|
| No. | 2-10 | 2-11 |
| Structure unit | 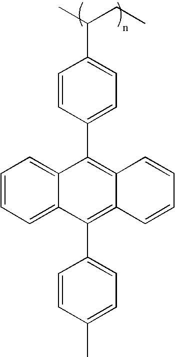 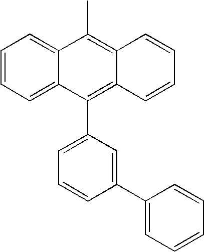 | 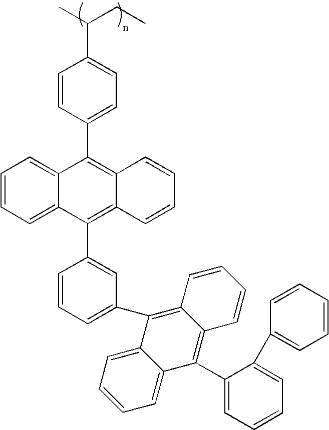 |
| No. | 2-12 | 2-13 |
| Structure unit | 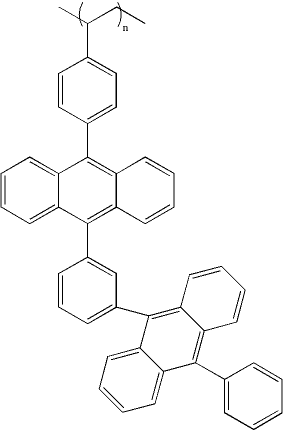 | 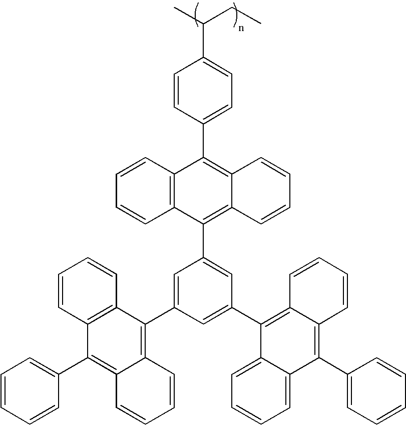 |

The structure unit represented by the following general formula (3) will now be explained.

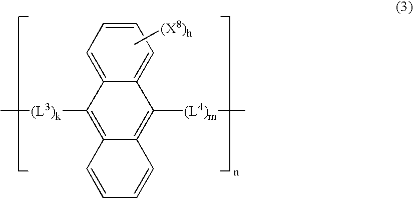

In general formula (3), L³ and L⁴ are bivalent organic groups, k and m are each 0 or 1, and (k+m) is at least 1. The bivalent organic groups represented by L³ and L⁴ are not limited in particular as long as they are organic groups which make the above-mentioned polymer nonconjugated. Namely, it will be sufficient if they are bivalent organic groups (which may include an aromatic ring) containing no single bond between two multiple bonds. Examples of L³ and L⁴ include substituted or unsubstituted alkylene groups, substituted or unsubstituted cycloalkylene groups, substituted or unsubstituted arylene groups, substituted or unsubstituted heterocyclic groups, oxy group (oxygen atom), carbonyl group, imino group, sulfonyl group, and bivalent organic groups combining at least one species of these groups.

In general formula (3), X⁸ is an alkyl group, alkoxy group, aryl group, aryloxy group, heterocyclic group, halogen atom, cyano group, hydroxyl group, or amino group; and h is an integer of 0 to 8. When h is an integer of 2 to 8, X⁸ substituting an anthrylene group may be either identical or different from each other.

When X⁸ is an alkyl group, the alkyl group may be either linear or branched. The alkyl group is preferably unsubstituted but may have a substituent. The carbon number in the alkyl group is 1 to 30. Preferred examples of the alkyl group include methyl, ethyl, n-propyl, isopropyl, n-butyl, isobutyl, s-butyl, t-butyl, and pentyl groups.

When X⁸ is an alkoxy group, the alkyl group constituting the alkoxy group may be linear or branched. The alkoxy group is preferably unsubstituted but may have a substituent. The carbon number in the alkoxy group is preferably 1 to 30. Preferred examples of the alkoxy group include methoxy, ethoxy, n-propoxy, isopropoxy, n-butoxy, isobutoxy, s-butoxy, and t-butoxy groups.

When X⁸ is an aryl group, the aryl group may be either substituted or unsubstituted, whereas the total carbon number in the aryl group is preferably 6 to 20. Preferred examples of the aryl group include phenyl, o-tolyl, m-tolyl, p-tolyl, and biphenylyl groups.

When X⁸ is an aryloxy group, the aryl group constituting the aryloxy group may be either substituted or unsubstituted, whereas the total carbon number in the aryloxy group is preferably 6 to 20. Preferred examples of the aryloxy group include phenoxy, o-tolyloxy, m-tolyloxy, and p-tolyloxy groups.

When X⁸ is a heterocyclic group, the heterocyclic group is preferably a 5- or 6-membered ring group. The heterocyclic group may have a condensed ring or a substituent. The heterocyclic group may have either an aromaticity or not. Preferred examples of heterocyclic group include pyrrolyl, pyridyl, quinolyl, thienyl, and furyl groups.

When X⁸ is a halogen atom, examples of the halogen atom include fluorine, chlorine, bromine, and iodine.

When X⁸ is an amino group, the amino group may be either substituted or unsubstituted. For example, it may have the above-mentioned alkyl or aryl group. The total carbon number in the amino group is preferably 0 to 20. Preferred examples of the amino group include amino group in the narrow sense (—NH₂) and methylamino, ethylamino, phenylamino, dimethylamino, and diphenylamino groups.

In general formula (3), n is an integer of 1 or greater, preferably such an integer that the weight average molecular weight of the nonconjugated polymer falls within the range of 5,000 to 1,000,000.

The nonconjugated polymer in accordance with the present invention is further preferably a nonconjugated polymer having a structure unit represented by the following general formula (3-1):

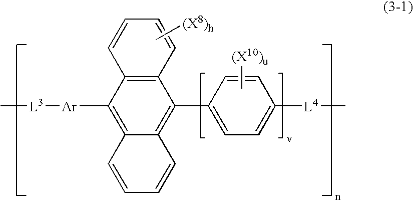

In general formula (3-1), L³ and L⁴ are bivalent organic groups. Those similar to L³ and L⁴ mentioned earlier can be used as L³ and L⁴, respectively. For example, substituted or unsubstituted alkylene groups, substituted or unsubstituted cycloalkylene groups, substituted or unsubstituted arylene groups, substituted or unsubstituted heterocyclic groups, oxy group (oxygen atom), carbonyl group, imino group, sulfonyl group, or bivalent organic groups combining at least one species of these groups can be used.

X⁸, h, and n are synonymous with those in general formula (3), respectively. Examples of X¹⁰ can be similar to those of X⁸ in general formula (3). Here, v is an integer of at least 1, and preferably is 1. While u is an integer of 0 to 4, X¹⁰ substituting a phenylene group may be identical or different from each other when u is an integer of 2 to 4.

Ar is a substituted or unsubstituted bivalent aromatic group, preferably a substituted or unsubstituted phenylene group, naphthylene group, or anthrylene group or a combination of these groups, more preferably an aromatic group represented by the following general formula (3-1-1), (3-1-2), (3-1-3), or (3-1-4).

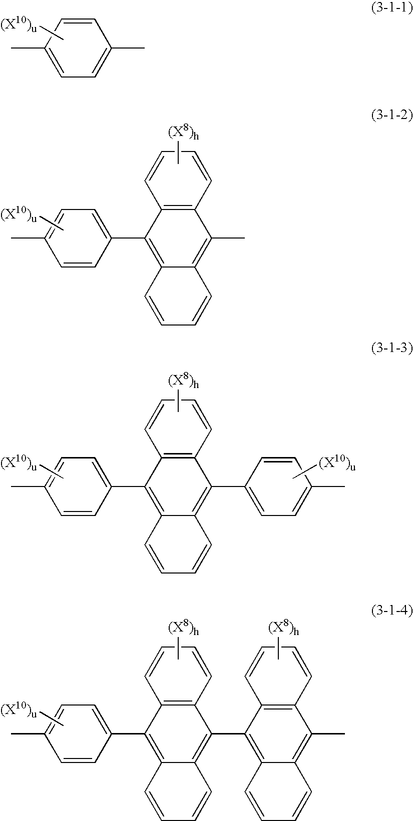

In each of general formulas (3-1-1), (3-1-2), (3-1-3), and (3-1-4), X⁸ and X¹⁰ are alkyl groups, alkoxy groups, aryl groups, aryloxy groups, heterocyclic groups, halogen atoms, cyano groups, hydroxyl groups, or amino groups, specific examples of which are similar to those of X⁸ in the above-mentioned general formula (1). Here, u is an integer of 0 to 4, whereas h is an integer of 0 to 8. When u is an integer of 2 to 4, X¹⁰ substituting a phenylene group may be either identical or different from each other. When h is an integer of 2 to 8, X⁸ substituting an anthrylene group may be either identical or different from each other.

In polymers having the structure unit represented by general formula (3), polymers having a structure unit represented by the following general formula (3-2), (3-3), or (3-4) is preferred in particular.

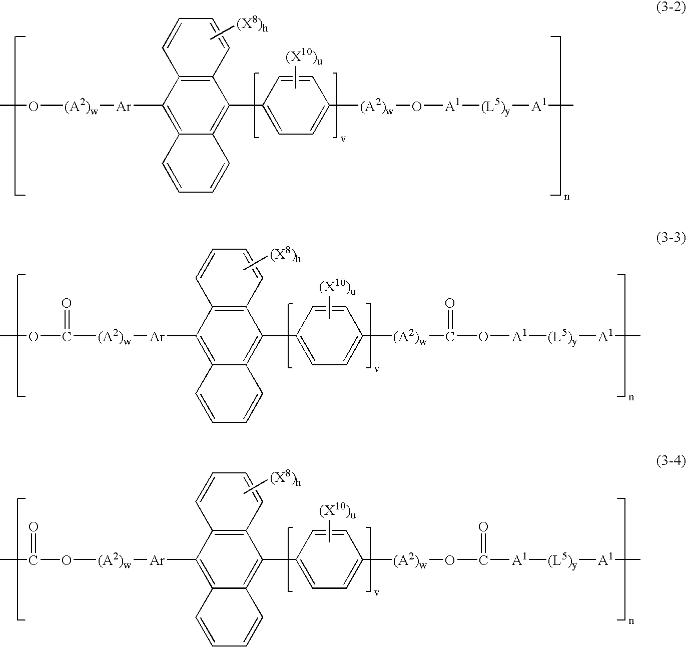

In each of general formulas (3-2), (3-3), and (3-4), L⁵ is a bivalent organic group constructed by way of a carbon atom or heteroatom. Specific examples of L⁵ include substituted or unsubstituted alkylene groups, substituted or unsubstituted cycloalkylene groups, substituted or unsubstituted arylene groups, substituted or unsubstituted heterocyclic groups, oxy group (oxygen atom), carbonyl group, imino group, and sulfonyl group. A¹ and A² are bivalent hydrocarbon groups, specific examples of which include substituted or unsubstituted alkylene groups, substituted or unsubstituted cycloalkylene groups, and substituted or unsubstituted arylene groups. Each of w and y is 0 or 1. When q is 0, the resulting structure is such that A¹, each of which is a bivalent hydrocarbon group, are directly combined to each other.

Ar, X⁸, X¹⁰, h, u, n, and v are synonymous with those in general formula (3-1), respectively. Namely, Ar is a substituted or unsubstituted bivalent aromatic group; X⁸ and X¹⁰ are alkyl groups, alkoxy groups, aryl groups, aryloxy groups, heterocyclic groups, halogen atoms, cyano group, hydroxyl group, or amino group; h is an integer of 0 to 8; u is an integer of 0 to 4; and n and v are each an integer of 1 or greater.

Examples of -A¹-(L⁵)_{y}-A¹- in general formula (3) include groups represented by the following formulas (3-5) to (3-9): 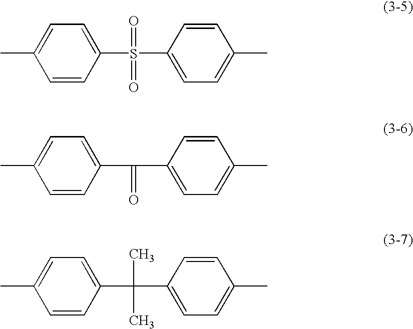 —CH₂—CH₂— (3-8)
—CH₂—CH₂—CH₂—CH₂— (3-9)

Examples of -A¹-(L⁵)_{y}-A¹- in general formulas (3-3) and (3-4) include the ethylene group represented by the above-mentioned formula (3-8) and the n-butylene group represented by the above-mentioned formula (3-9), whereas examples of A² are methylene and ethylene groups.

Specific examples of polymers having the structure units represented by general formulas (3-2), (3-3), and (3-4) include nonconjugated polymers having structure units represented by the following formulas (3-10), (3-11), (3-12), (3-13), and (3-14).

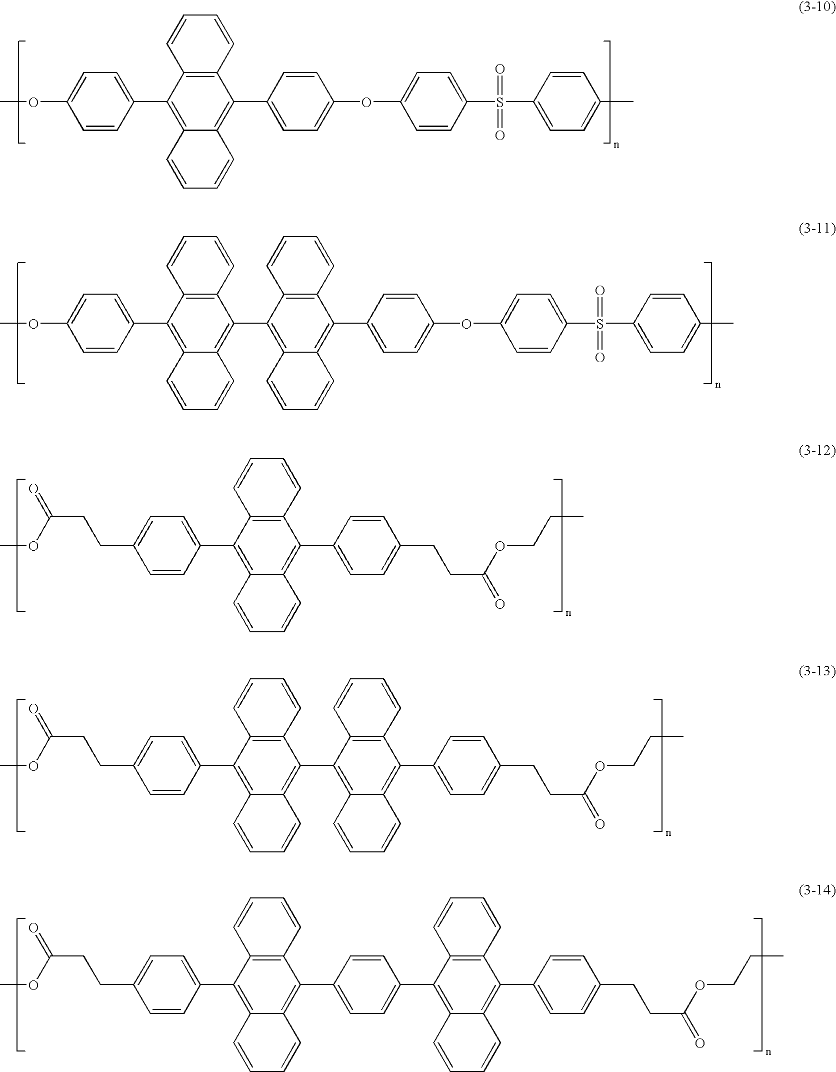

A polymer having the structure unit represented by the above-mentioned general formula (3) can be obtained by polymerizing a monomer including a nonconjugated monomer corresponding to the polymer, whereas deacidification, ester exchange reaction, or the like can be employed as a polymerization method. The polymer in accordance with the present invention may be either a homopolymer made of one species of the above-mentioned structure unit or a copolymer made of two or more species of the above-mentioned structure unit, and may further contain structure units other than those represented by the above-mentioned general formula (3). When the polymer is a copolymer, it may be either a block copolymer or random copolymer.

The structure unit represented by the following general formula (4) will now be explained. 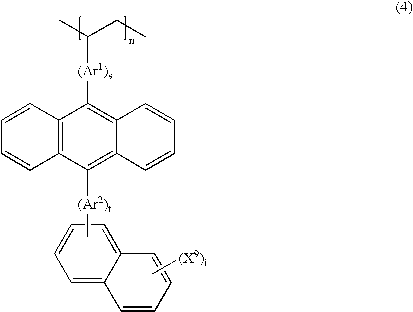
where Ar¹ and Ar² may be either identical or different from each other, each representing a substituted or unsubstituted phenylene group or substituted or unsubstituted naphthylene group; X⁹ is an alkyl group, alkoxy group, aryl group, aryloxy group, heterocyclic group, halogen atom, cyano group, hydroxyl group, or amino group; s is 1 or 2; t is 0 or 1; i is an integer of 0 to 7; and n is an integer of at least 1.

In general formula (4), Ar¹ and Ar² may be either identical or different from each other, each representing a substituted or unsubstituted phenylene group or substituted or unsubstituted naphthylene group. Examples of substituents for Ar¹ and Ar² include alkyl groups, alkoxy groups, aryl groups, aryloxy groups, heterocyclic groups, halogen atoms, cyano group, hydroxyl group, and amino group. On the other hand, s is 1 or 2, whereas t is 0 or 1. When t is 0, the structure is such that a naphthyl group is directly bound to the 10-position of an anthracene skeleton.

X⁹ is an alkyl group, alkoxy group, aryl group, aryloxy group, heterocyclic group, halogen atom, cyano group, hydroxyl group, or amino group; i is an integer of 0 to 7; and n is an integer of at least 1.

Specific preferred examples of the structure unit represented by general formula (4) include structure units (4-1) to (4-9) shown in the following Table 7. In each of the formulas representing the structure units, n is an integer of 1 or greater. The polymer in accordance with the present invention may be either a homopolymer made of one species of the following structure units or a copolymer made of two or more species of the following structure units, and may further contain structure units other than those represented by the above-mentioned general formula (4). When the polymer is a copolymer, it may be either a block copolymer or random copolymer.

TABLE 7

| | | | |
|---|---|---|---|
| No. | 4-1 | 4-2 | 4-3 |
| Structure unit | 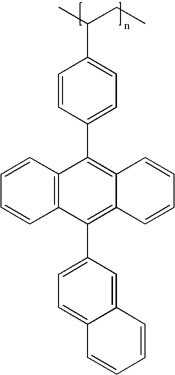 | 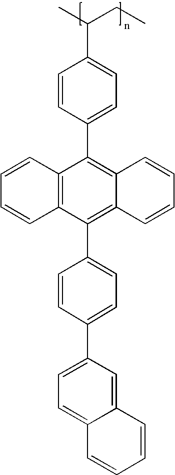 | 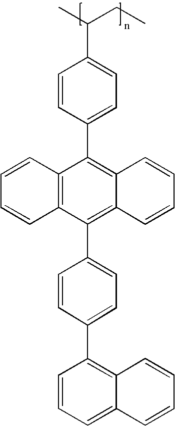 |
| No. | 4-4 | 4-5 | 4-6 |
| Structure unit | 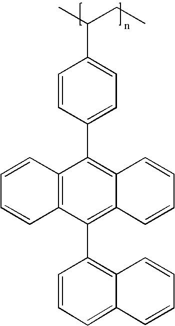 | 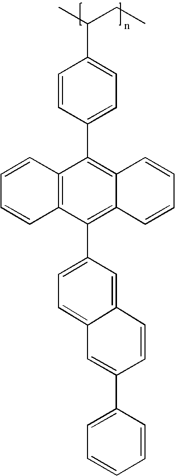 | 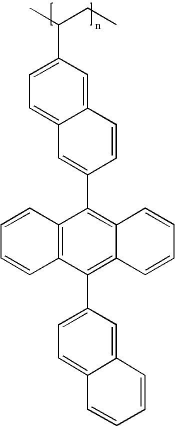 |
| No. | 4-7 | 4-8 | 4-9 |
| Structure unit | 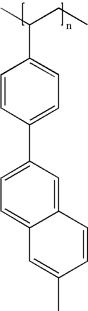 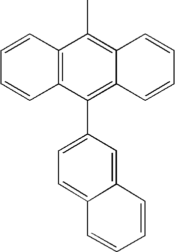 | 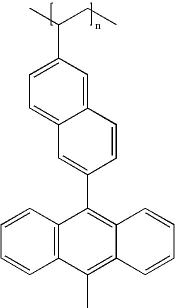 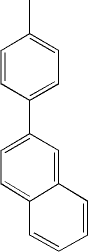 | 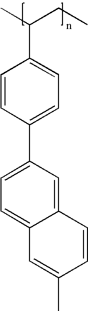 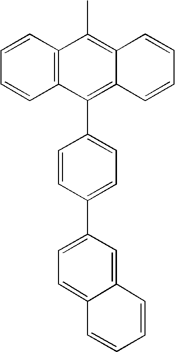 |

The vinyl polymer having the structure unit represented by the above-mentioned general formula (4) can be obtained by polymerizing a vinyl monomer which is a material therefor. The polymerizing method is not restricted in particular, whereby polymerization can easily be achieved by radical polymerization, cationic polymerization, anionic polymerization, and the like.

From the viewpoint of elongating the life of the organic EL device, the content of the vinyl polymer having an anthracene structure is preferably 30 to 99 mass %, more preferably 50 to 90 mass %, based on the total amount of constituent materials of the luminescent layer 20A.

The luminescent layer 20A may further contain polymers other than the vinyl polymer having the anthracene structure. However, on the basis of the total amount of the vinyl polymer having the anthracene structure and the other polymers, the content of the former polymer is preferably at least 50 mass %, more preferably at least 80 mass %, for achieving a longer life.

On the other hand, the luminescent layer 20A contains a hole-transferring compound having a glass transition temperature of at least 70° C. (preferably 90 to 150° C.). The molecular weight of the hole-transferring compound is not restricted in particular as long as it can be dispersed and held within the vinyl polymer having the anthracene structure, but preferably is 400 or greater.

The hole-transferring compound is not restricted in particular as long as the glass transition temperature satisfies the above-mentioned condition. For example, triphenylamine derivatives, pyrazoline derivatives, arylamine derivatives, and stilbene derivatives are usable, among which triphenylamine derivatives are preferred.

Preferred examples of the triphenylamine derivatives used in the present invention include low-molecular compounds and polymer compounds having a structure represented by the following general formula (5) and a glass transition temperature of at least 70° C.

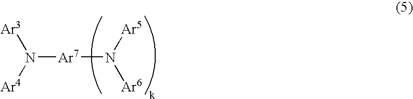

In formula (5), Ar³, Ar⁴, Ar⁵, and Ar⁶ may be either identical or different from each other, each representing a substituted or unsubstituted aryl group (e.g., phenyl or biphenyl group). When any of Ar³ to Ar⁶ is a substituted aryl group, its substituents include not only alkyl and aryl groups, etc., but those having a triphenylamine structure. On the other hand, k is 0 or 1, whereas Ar⁷ is a substituted or unsubstituted aryl group and a substituted or unsubstituted arylene group when k is 0 and 1, respectively.

Specific examples of the low-molecular hole-transferring compound having the structure represented by the above-mentioned general formula (5) and a glass transition temperature of at least 70° C. include triphenylamine derivatives (5-1) to (5-20) shown in the following Tables 8 to 11. The following tables also list respective glass transition temperatures (Tg) of the hole-transferring compounds.

TABLE 8

| | | |
|---|---|---|
| No. | 5-1 | 5-2 |
| Structure unit | 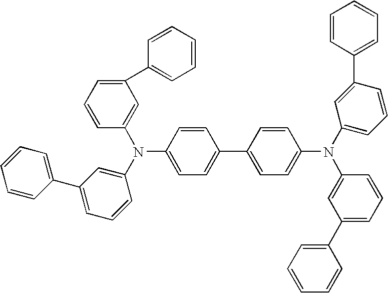 Tg: 98° C. | 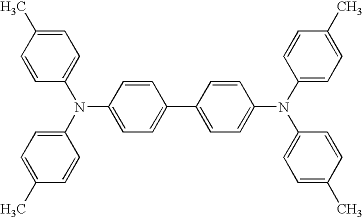 Tg: 83° C. |
| No. | 5-3 | 5-4 |
| Structure unit | 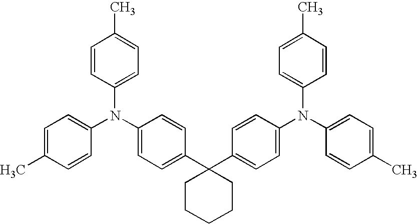 Tg: 76° C. | 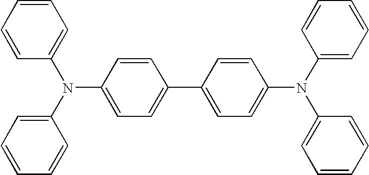 Tg: 73° C. |
| No. | 5-5 | 5-6 |
| Structure unit | 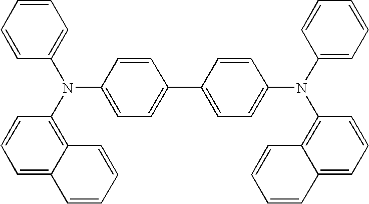 Tg: 95° C. | 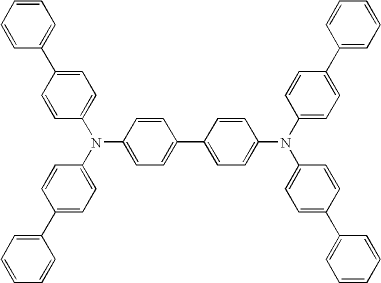 Tg: 131.8° C. |

TABLE 9

| | | |
|---|---|---|
| No. | 5-7 | 5-8 |
| Structure unit | 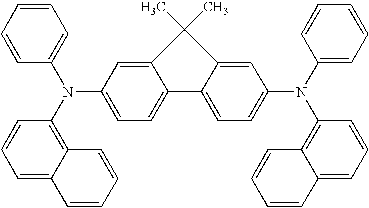 Tg: 114° C. | 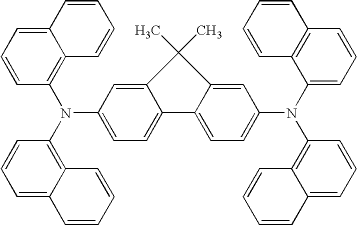 Tg: 169° C. |
| No. | 5-9 | 5-10 |
| Structure unit | 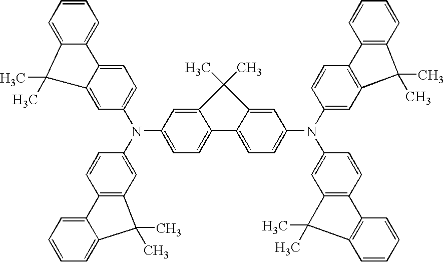 Tg: 186° C. | 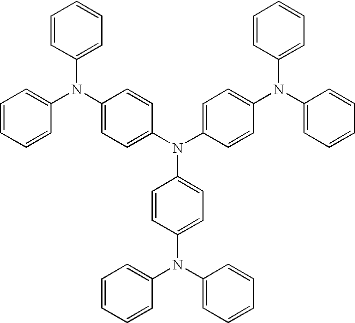 Tg: 89° C. |
| No. | 5-11 | 5-12 |
| Structure unit | 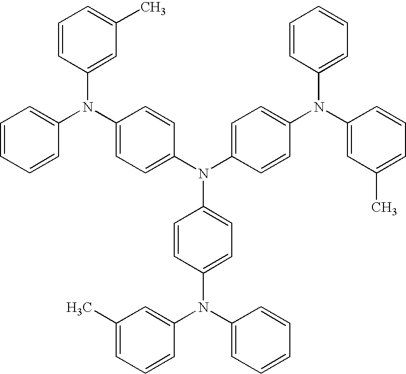 Tg: 76° C. | 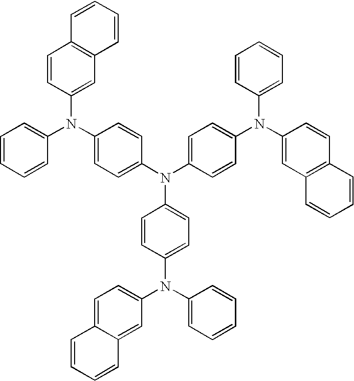 Tg: 110° C. |

TABLE 10

| | | |
|---|---|---|
| No. | 5-13 | 5-14 |
| Structure unit | 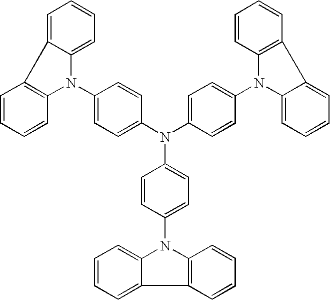 Tg: 151° C. | 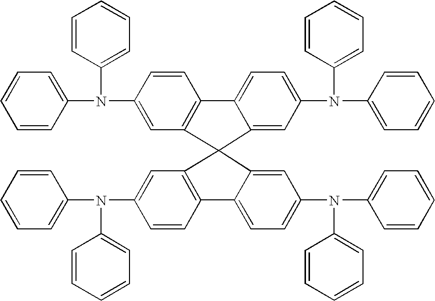 Tg: 133° C. |
| No. | 5-15 | 5-16 |
| Structure unit | 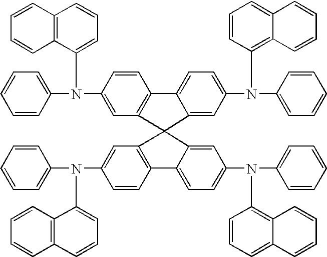 Tg: 147° C. | 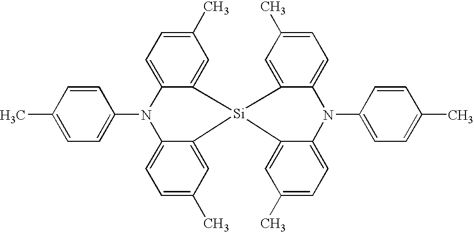 Tg: 144° C. |

TABLE 11

| | |
|---|---|
| No. | 5-17 |
| Structure unit | 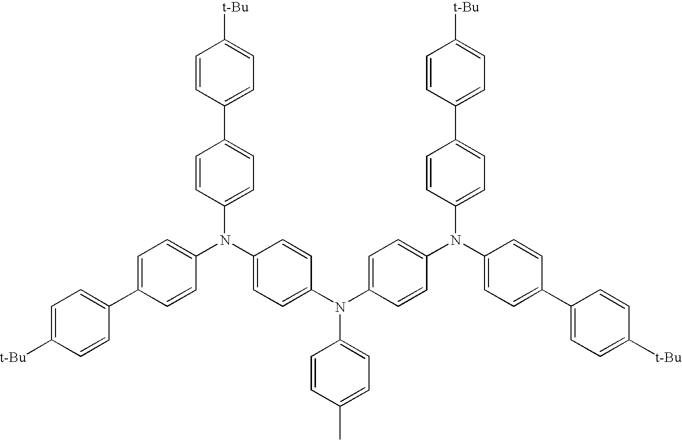 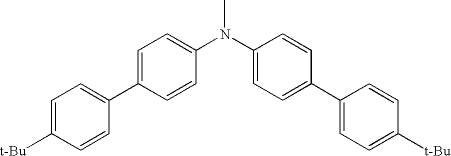 Tg: 203° C. |
| No. | 5-19 |
| Structure unit | 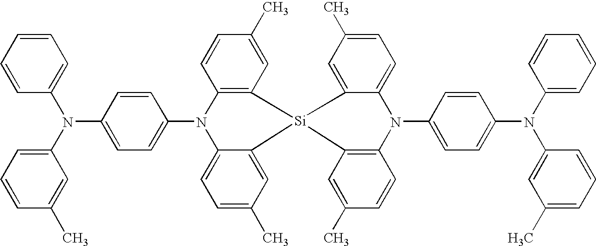 Tg: 156° C. |
| No. | 5-20 |
| Structure unit | 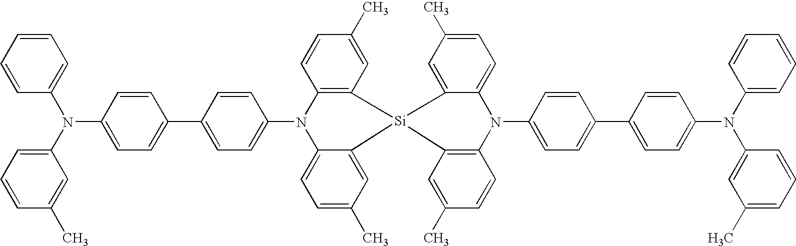 Tg: 178° C. |

Preferred as polymer compounds having the structure represented by the above-mentioned general formula (5) and a glass transition temperature of at least 70° C. are those having a structure unit represented by the following general formula (5-a) or (5-b).

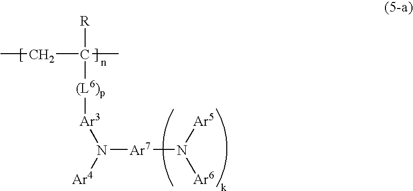

In general formula (5-a), L⁶ is a bivalent group; p is 0 or 1; n is an integer of at least 1; and Ar³, Ar⁴, Ar⁵, Ar⁶, Ar⁷, and k are defined as with those in the above-mentioned formula (5), respectively. Usable examples of the bivalent group represented by L⁶ include substituted or unsubstituted alkylene groups, substituted or unsubstituted cycloalkylene groups, substituted or unsubstituted arylene groups, substituted or unsubstituted heterocyclic groups, oxy group (oxygen atom), carbonyl group, imino group, sulfonyl group, and bivalent organic groups combining at least one species of these groups. When p is 0, the structure is such that Ar³ is directly bound to the main chain.

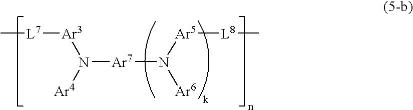

In general formula (5-b), L⁷ and L⁸ are bivalent groups; n is an integer of at least 1; and Ar³, Ar⁴, Ar⁵, Ar⁶, Ar⁷, and k are defined as with those in the above-mentioned formula (5), respectively. Usable examples of the bivalent groups represented by L⁷ and L⁸ include substituted or unsubstituted alkylene groups, substituted or unsubstituted cycloalkylene groups, substituted or unsubstituted arylene groups, substituted or unsubstituted heterocyclic groups, oxy group (oxygen atom), carbonyl group, imino group, sulfonyl group, and bivalent organic groups combining at least one species of these groups. When k is 0, the structure is such that Ar⁷ and L⁸ are directly bound to each other.

From the viewpoint of elongating the life of the organic EL device, the content of the hole-transferring compound having a glass transition temperature of at least 70° C. is preferably 5 to 50 mass %, more preferably 10 to 40 mass %, based on the total amount of the constituent materials of the luminescent layer 20A.

Also from the viewpoint of elongating the life of the organic EL device, the ratio between the vinyl polymer having a side chain group including an anthracene structure and the hole-transferring compound having a glass transition temperature of at least 70° C. is such that the latter is preferably 5 to 50 parts, more preferably 10 to 40 parts, with respect to 100 parts of the former in terms of mass ratio.

In the luminescent layer 20A, the polymer having the anthracene structure functions as a host material, whereby doping it with a luminous dopant as a guest material can yield a desirable emission color. For example, iridium complexes such as tris(2-phenylpyridine)iridium (Ir(ppy)₃) and platinum complexes having a porphyrin ring such as 2,3,7,8,12,13,17,18-octaethyl-21H,23H-porphyrin platinum (PtOEP) can be used as a phosphorescent dopant. On the other hand, tetraphenyl butadiene and its derivatives, styrylamine derivatives, fluoranthene derivatives, and the like can be used as a blue-emitting dopant. The ratio of the luminous dopant is preferably 1 to 30 mass % with respect to the total amount of polymerizable monomers before polymerization.

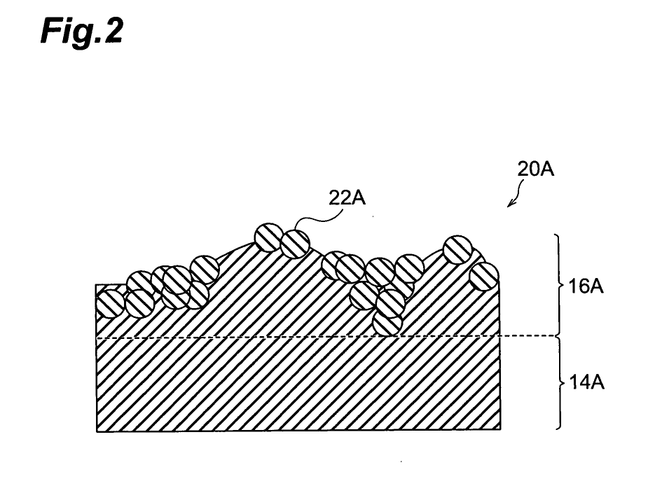

The modified part 16A of the luminescent layer 20A is constructed so as to contain a hole-blocking compound having an ionization potential of at least 5.5 eV. FIG. 2 is an explanatory view schematically showing an example of the state of the luminescent layer 20A having the modified part 16A near the surface on the electron-injecting electrode layer 18 side. In FIG. 2, particles 22A of the hole-blocking compound exist at all the positions in the thickness direction of the modified part 16A. In the part 14A other than the modified part 16A, on the other hand, no particles 22A of the hole-blocking compound exist at any position in the thickness direction.

Also, as shown in FIG. 2, the surface of the luminescent layer 20A has a certain degree of irregularities since it contains a polymer. When forming the luminescent layer 20A by a coating method, particles 22A of the hole-blocking compound seem to exist in a so-called infiltrated state, thereby forming the modified part 16A. Since the surface of the luminescent layer 20A has irregularities, the adhesion of particles 22A of the hole-blocking compound to the luminescent layer 20A increases drastically, whereby the particles 22A of hole-blocking compound are harder to peel off once the modified part 16A is formed. It seems that the polymer compound existing near such an irregular surface can relatively easily form the modified part 16A with a concentration gradient such as that mentioned above, thereby effectively contributing to recombination between holes and electrons in the luminescent layer. The luminous efficiency and life of the organic EL device are assumed to improve because of the foregoing.

Polymer compounds and organic metal compounds having a bandgap of at least 4.0 eV are preferably used as the hole-blocking compound contained in the modified part 16A.

Polar polymer compounds are preferably used as the polymer compounds having a bandgap of at least 4.0 eV. The polar polymer compounds encompass homopolymers made of one species of monomers having a polar group, copolymers made of two or more species of monomers having a polar group, copolymers formed between a monomer having a polar group and a monomer having no polar group, those in which a polar group is introduced to a terminal of a polymerized chain of a polar or nonpolar polymer.

Specific examples of the polymer compounds having a polar group include polymers of unsaturated alcohols or unsaturated ethers or copolymers of an unsaturated alcohol and an unsaturated ether such as polyvinyl alcohol, polyaryl alcohol, polyvinyl ether, and polyaryl ether; polyethers; cellulose derivatives; polymers or copolymers of unsaturated carboxylic acids such as acrylic acid and methacrylic acid; polymers or copolymers of those having an unsaturated bond in an alcohol residue such as polyvinyl esters like polyvinyl acetate and polyacrylic esters like polyphthalic acid; polymers or copolymers of those having an unsaturated bond in an acid residue or in acid and alcohol residues such as polyacrylic acid esters, polymethacrylic acid esters, maleic acid ester polymers, and fumaric acid ester polymers; acrylonitrile polymers, methacrylonitrile polymers, copolymers of acrylonitrile and methacrylonitrile, polyvinylidene cyanide, malononitrile polymers, fumaronitrile polymers, copolymers of malononitrile and fumaronitrile; polymers or copolymers of heterocyclic compounds such as polyvinylpyridine, poly-N-vinylpyrrolidine, and poly-N-vinylpyrrolidone; and polymethyl methacrylate (PMMA). These may be used singly or in combination of two or more species.

Among them, poly(2-vinylpyridine), poly(4-vinylpyridine), polyacrylic acid, polymethacrylic acid, poly(N,N-dimethylacrylamide), poly(ethylene glycol), polypropylene glycol, poly(2-ethyl-2-oxazoline), poly(2-hydroxyethyl acrylate), poly(2-ethyl-2-oxazoline), poly(2-hydroxyethyl methacrylate), poly(tetramethylene ether) glycol, polyvinyl acetate, polyvinyl butyral, substituted polystyrene, and poly-N-vinyl pyrrolidone are preferably used from the viewpoint of further enhancing the luminous efficiency and life of the organic EL device 1A.

The weight average molecular weight (Mw) of such a polymer compound is preferably at least 2,000 from the viewpoint of capability of appropriately forming a concentration gradient which will be explained later. When Mw is less than 2,000, the luminous efficiency of the organic EL device 1A tends to decrease, thereby shortening the life. This seems to be because the film quality lowers so that flocculation and the like are likely to occur, whereby the modified part 16A does not function appropriately as a blocking layer against holes.

The organic metal compounds refer to those obtained when substituting hydrogen in organic acids, alcohols, and dialkylamides with a metal, while excluding those solely consisting of coordinate bonds between the metal and ligand, though they may partly include coordinate bonds. Examples of the organic metal compounds include salts of organic acids such as carboxylic acid and phenol, and salts of alkoxides and dialkylamides.

The carboxylic acid may be either aliphatic or aromatic. Preferred as the aliphatic carboxylic acid is one having a total carbon number of 1 to 24, which may be either a saturated or unsaturated aliphatic carboxylic acid, and may have two or more carboxyl groups. It may have a substituent such as aryl group. Specific examples include aliphatic carboxylic acids such as acetic acid, propionic acid, octyl acid, isooctyl acid, decanoic acid, and lauric acid; unsaturated aliphatic carboxylic acids such as oleic acid and ricinoleic acid; and polyhydric carboxylic acids such as dicarboxylic and tricarboxylic acids like citric acid, malic acid, and oxalic acid. Preferred as the aromatic carboxylic acid is one having a total carbon number of 7 to 24, which may have a substituent (an alkyl group having a carbon number of 1 to 8, a hydroxyl group, or the like). Specific examples include benzoic acid, o-(t-butyl)benzoic acid, m-(t-butyl)benzoic acid, salicylic acid, m-(hydroxy)benzoic acid, and p-(hydroxy)benzoic acid.

Preferred as phenol is one having a total carbon number of 6 to 46, which may have a substituent (a linear or branched alkyl group having a carbon number of 1 to 8, an aryl group such as phenyl group, or the like) and a condensed ring (e.g., an aromatic ring such as benzene ring which may have a substituent), and may be monohydric phenol or polyhydric phenol of dihydric or higher. Specific examples include phenol, naphthol, 4-phenylphenol, and 2,2-bis(p-hydroxyphenyl)propane (bisphenol A).

Preferred as the alcohol forming the alkoxide is one having a total carbon number of 1 to 10, examples of which include primary alcohols such as ethyl alcohol, n-propyl alcohol, and n-butyl alcohol; secondary alcohols such as isopropyl alcohol and s-butyl alcohol; and tertiary alcohols such as t-butyl alcohol. It may be a polyhydric alcohol of dihydric or higher, an example of which is ethylene glycol.

The dialkyl amide may further have a substituent, whereas its total carbon number is preferably 2 to 24. Specific examples include dimethylamide, diethylamide, and N-methyl-N-ethylamide.

Alkoxides, phenoxides, acetates, and the like are preferred among the organic metal compounds.

Specific examples of the organic metal compounds include compounds represented by the following formulas (C-1) to (C-27). They may be used singly or in combinations of two or more species.

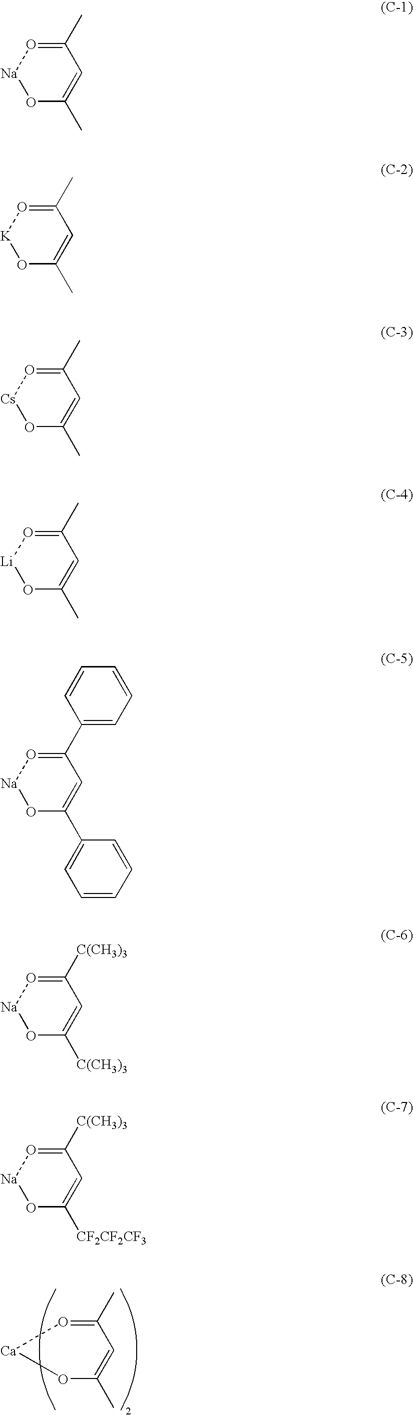

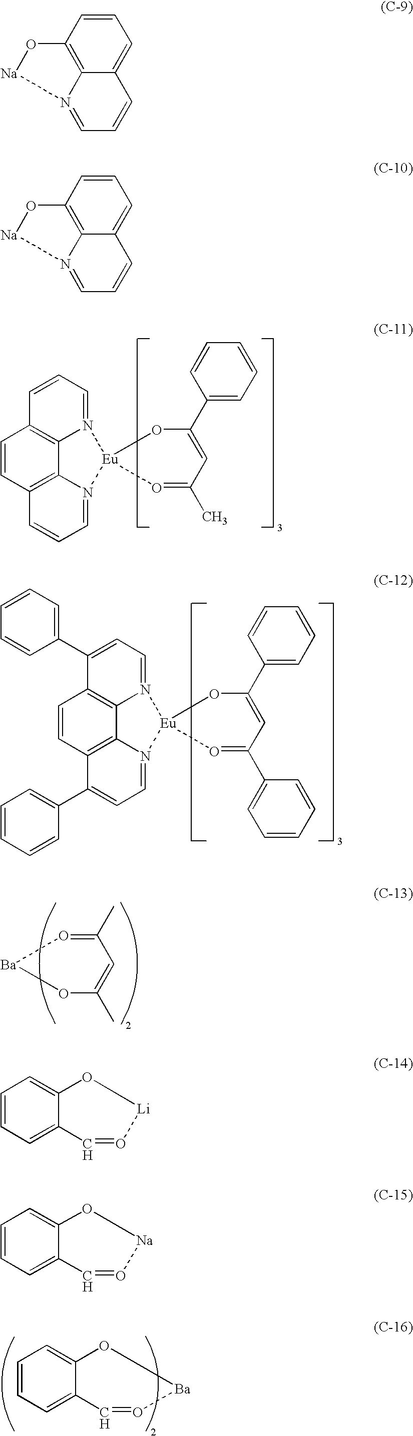

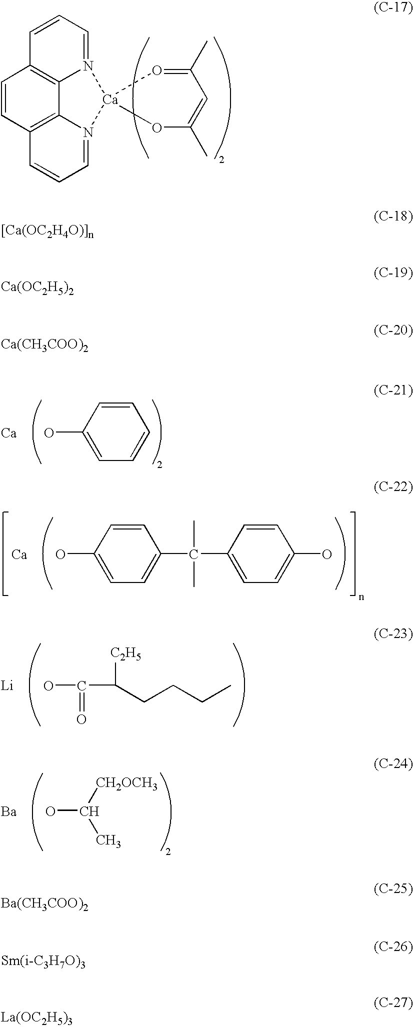

Here, the weight average molecular weight in each of the above-mentioned formulas (C-18) and (C-22) is preferably 5,000 to 500,000, more preferably 20,000 to 300,000.

The modified part 16A in the luminescent layer 20A can favorably be formed by coating with a solution containing a hole-blocking compound having an ionization potential of at least 5.5 eV. Any solvent can be used in such a solution without being restricted in particular, as long as it can dissolve the hole-blocking compound. A polar solvent is preferably used from the viewpoint of coatability, solubility, and the like. When a nonpolar solvent is used, a desirable modified part 16A may be harder to form depending on compounds used for coating. Examples of the polar solvent include N,N-dimethylacetamide and 2-ethoxyethanol, in which 2-ethoxyethanol is used more preferably.

In the modified part 16, the thickness of the hole-blocking compound contained therein is preferably 5.0×10⁻⁹ to 1.0×10⁻⁶ g/cm², more preferably 2.5×10⁻⁸ to 5.0×10⁻⁷ g/cm². Since the modified part 16A contains a hole-blocking compound having such a thickness, the organic EL device can effectively improve the luminous efficiency and attain a sufficiently long life. When the thickness of the hole-blocking compound exceeds 1.0×10⁻⁶ g/cm², electrons are harder to pass through the modified part 16A, thus making it more difficult for the organic EL device 1A to emit light.

The thickness of the hole-blocking compound can be adjusted by appropriately regulating various conditions under which the modified part 16A is formed. When forming the modified part 16A by the above-mentioned coating, for example, the thickness can be adjusted by regulating the concentration of the hole-blocking compound in the coating solution, coating time, amount of the coating solution, etc.

The method of carrying out the coating (coating method) is not restricted in particular. For example, spin coating, spray coating, dip-coating, ink jetting, and printing can be employed.

The thickness of the luminescent layer 20A is not restricted in particular and varies depending on the forming method. From the viewpoint of further improving the luminous efficiency, the thickness is preferably 20 to 150 nm.

Though a preferred embodiment of the organic EL device in accordance with the present invention is explained in the foregoing, the present invention is not limited to the above-mentioned embodiment. For example, though the hole-injecting electrode layer 12 side is employed as the light exit side in the above-mentioned embodiment, the electron-injecting electrode layer, luminescent layer, and hole-injecting electrode layer may be laminated successively from the substrate, so that the electron-injecting electrode layer side is used as the light exit side. In this case, it will be preferred if the electron-injecting electrode layer satisfies the optical and thickness conditions in the case where the hole-injecting electrode layer is employed as the light exit side.

Though the above-mentioned embodiment includes only one luminescent layer, the luminescent layer in the organic EL device in accordance with the present invention may have a multilayer structure in which a plurality of luminescent layers are laminated. The organic EL device may further comprise a hole-injecting layer, a hole-transferring layer, an electron-transferring layer, and the like in addition to the luminescent layer. In this case, the hole-injecting layer may be laminated adjacent to the hole-injecting electrode layer on the luminescent layer side, the hole-transferring layer may be laminated between the hole-injecting layer and the luminescent layer, and the electron-transferring layer may be laminated between the electron-injecting electrode layer and the luminescent layer.

Examples of the hole-transferring material used in the hole-transferring layer and the electron-transferring material used in the electron-transferring layer include those mentioned above. Examples of the hole-injecting material used in the hole-injecting layer include known conductive polymer compounds such as polythiophene and polyaniline.

When forming the above-mentioned organic layers by such a coating method, the thickness per species of organic layer is preferably 0.5 to 1,000 nm, more preferably 10 to 500 nm. When the thickness of the organic layers is large, at least 20 nm in particular, leak currents can be prevented from occurring.

Preferably, for preventing the organic layers and electrodes in the device from deteriorating, the upper side of the device is sealed with a sealing plate or the like. For preventing moisture from entering, an adhesive resin layer is used for bonding and tightly sealing the sealing plate. The sealing gas is preferably an inert gas such as Ar, He, or N₂, etc. The moisture content in the sealing gas is preferably 100 mass ppm or less, more preferably 10 mass ppm or less, 1 mass ppm or less in particular. Though the moisture content has no lower limit in particular, the lower limit is usually about 0.1 mass ppm.

A preferred embodiment of the method of manufacturing an organic EL device in accordance with the present invention will now be explained in detail. Here, a method of manufacturing an organic EL device configured as shown in FIG. 1 will be explained.

First, on a substrate 10 prepared, a hole-injecting electrode layer 12 such as ITO is formed. As its forming method, a conventionally used method such as sputtering or vapor deposition can be employed.

Next, a luminescent layer 20A is formed on the hole-injecting electrode layer 12. As its forming method, a coating method such as spin coating, spray coating, dip-coating, ink jetting, or printing can be employed.

Subsequently, for forming a modified part 16A near the surface of the luminescent layer 20A, a solution in which such a hole-blocking compound as that mentioned above is added to a predetermined solvent (which is preferably a polar solvent) is applied to the surface of the luminescent layer 20A. The coating method is not restricted in particular, whereby spin coating, spray coating, dip-coating, ink jetting, or printing, for example, can be employed.

Preferably, the concentration of the nonluminous polymer in the solution is adjusted such that the modified part 16A attains a desirable thickness. The concentration is preferably 0.01 to 1.0 mass %. This range indicates a concentration much lower than that of the solution used when forming an organic layer containing a polymer compound in the conventional organic EL device by a coating method. Coating with a solution having such a concentration tends to be able to provide the modified part 16A with an appropriate concentration gradient.

Then, an electron-injecting electrode layer 18 is formed on the luminescent layer 20A, so as to complete the organic EL device 1A. As its forming method, a conventionally used method such as vapor deposition or sputtering can be employed.

For forming an interface between two organic layers when manufacturing an organic EL device in which a plurality of organic layers are laminated, it will be sufficient if the coating surface of the lower layer is dried to form a film, and then an upper layer is applied thereto. In this case, heating or the like may be carried out if necessary after applying the lower layer.

When no interface is formed between two organic layers, the boundary of the two layers may be formed so as to yield a so-called slanted composition. Namely, coating with materials which differ from each other in at least one of the solubility to the solvent, solvent, viscosity, and specific gravity can apply two species of organic layers differently and change the boundary composition like a slope. Before drying the coating surface of the lower layer, the next layer may be applied thereto, so that no interface is formed.

The first organic EL display in accordance with the present invention will now be explained.

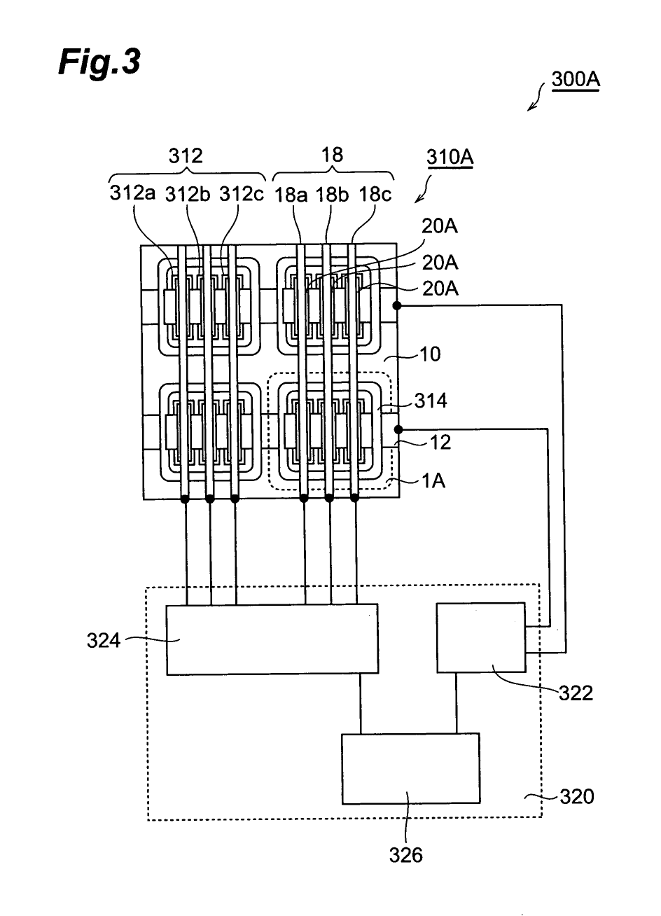

FIG. 3 is a block diagram showing a preferred embodiment of the first organic EL display. The organic EL display 300A shown in FIG. 3 is a passive driving organic EL display of color conversion type using a blue-emitting device as a pumping light source. The color conversion is a method in which fluorescent elements for three colors are pumped with visible light emission of a high-energy line. The color conversion typically generates blue emission in an organic layer of the organic EL device, and pumps green and red fluorescent surfaces with the blue emission as a pumping light energy line, so as to yield green light and red light. This scheme is known as color conversion, since blue is converted into green and red.

In FIG. 3, a display part 310A is one in which a plurality of organic EL devices 1A, each constituted by a substrate 10, a hole-injecting electrode layer 12 formed on one side of the substrate 10, luminescent layers 20A formed on the hole-injecting electrode layer 12, and an electron-injecting layer 18 formed on the luminescent layers 20A, are arranged two-dimensionally. In each of the organic EL devices 1A, three luminescent layers 20A, each containing a vinyl polymer having a side chain group containing an anthracene structure, a hole-transferring compound having a glass transition temperature of at least 70° C., and a blue-emitting dopant, are formed so as to correspond to three luminous regions 312 (e.g., 312a, 312b, 312c). In the three luminous regions 312a to 312c, one is a blue-emitting region, whereas the remaining two are green- and red-emitting regions, respectively.

Preferred examples of the material of the substrate 10 include transparent or semitransparent materials such as glass, silica, and resin.

On the substrate 10, respective regions corresponding to two of the three luminous regions formed in one organic EL device are provided with fluorescence conversion filter films as mentioned above, so as to become green- and red-emitting regions, respectively, as their emission colors are controlled by the fluorescence conversion filter films. The luminous region provided with no fluorescence conversion filter film is the blue-emitting region.

Each fluorescence conversion filter film, which absorbs light generated by electroluminescence in the luminous layer 20A and causes a phosphor in the film to emit light in a color different from that of the absorbed light so as to convert the emission color into another color, is typically constructed so as to contain the phosphor, a light absorber, and a binder. The fluorescence conversion filter film can be formed by patterning utilizing a technique such as photolithography or printing. Preferably, in this case, the material of the fluorescence conversion filter material is capable of forming a fine patterning and less likely to be damaged in the step of forming the upper layer (e.g., hole-injecting electrode layer 12).

Preferably, the phosphor contained in the fluorescence conversion filter film has a high fluorescent quantum efficiency and exhibits a high light absorption in the emission wavelength range of the luminescent device as with a laser dye. Examples of such a phosphor include rhodamine-based compounds, perylene-based compounds, cyanine-based compounds, phthalocyanine-based compounds such as subphthalocyanine, naphthalimide-based compounds, condensed-ring-hydrocarbon-based compounds, condensed heterocyclic compounds, styryl-based compounds, and coumarin-based compounds. When the light absorption of the phosphor itself is insufficient, a light absorber is preferably used therewith, whereas one which does not extinguish the fluorescence is preferred as the light absorber.

The binder is not restricted in particular as long as it does not extinguish the fluorescence, and can appropriately be chosen for use from among known binders.

Preferably, a color filter which cuts off external light having a short wavelength absorbable by constituent materials of the organic EL device 1A and the fluorescence conversion filter film is combined with the fluorescence conversion filter film, since the light resistance and display contrast of the device are further improved thereby.

In the display part 310A, two hole-injecting electrode layers are formed in parallel on the substrate 1 and fluorescence conversion filter film so as to pass the three luminous regions 312a to 312c in each organic EL device 1A. Here, each hole-injecting electrode layer 12 is arranged so as to partly expose each of the luminous regions 312a to 312c without completely covering them. Each hole-injecting electrode layer 12 is a common electrode for a plurality of (two in FIG. 3) organic EL devices, whereas a power supply part 322 which will be explained later is electrically connected to one end each of the hole-injecting electrode layers 12. Such a stripe-like hole-injecting electrode layer 12 can be formed, for example, by forming an ITO film on the substrate 10 having the fluorescence conversion filter film patterned thereon, and then carrying out patterning and etching.

Though not depicted in detail, after forming the hole-injecting electrode layer 12, an insulator layer such as SiO₂ layer or Al₂O₃ layer is preferably provided thereon. Then, preferably, regions of the insulator layer corresponding to the luminous regions are opened by etching or the like, and luminescent layers 20A are formed in these openings.

In the display part 310A, the luminescent layers 20A are formed so as to cover their corresponding luminous regions in the organic EL devices 1A while riding over the hole-injecting electrode layers 12. The luminescent layers 20A can favorably be formed by a coating method such as spin coating. Heating the coating liquid can reduce the residual solvent, thereby achieving a high adhesion between each of the luminescent layers 20A to each of the hole-injecting electrode layers 12 and electron-injecting electrode layers 18.

In the display part 310A, six electron-injecting electrode layers 18 are formed so as to pass over the luminescent layers 20A while corresponding to the luminous regions of the organic EL devices 1A. Each of the electron-injecting electrode layers 18 is a common electrode for a plurality of (two in FIG. 3) organic EL devices 1A, whereas a switching part 324 which will be explained later is connected to one end each of the electron-injecting electrode layers 18.

In a passive driving organic EL device as with this embodiment, it will be preferred if the stripe-like hole-injecting electrode layers 12 and stripe-like electron-injecting electrode layers 18 are arranged such that their extending directions are orthogonal to each other as shown in FIG. 3. Here, each intersection between the extending direction of the hole-injecting electrode layer 12 and the electron-injecting electrode layer 18 in each luminous region corresponds to one pixel of the display.

In the nonluminous region of the display part 310A, a spacer 314 is provided for each organic EL device 1A. Attaching a sealing plate (not depicted) to the spacer 314 seals the surface on the electron-injecting electrode layer 18 side.

In the organic EL display 300A, a driving part 320 for controlling the display in the display part 310A is constructed so as to include the power supply part 322 for supplying a current or voltage to the hole-injecting layers 12 and electron-injecting electrode layers 18, the switching part 324 for sending an on/off control signal to the organic EL device 1A, and their control logic circuit 326. The power supply part 322 is electrically connected to the hole-injecting electrode layers 12, whereas the switching part 324 is electrically connected to electron-injecting electrode layers 18. The power supply part 322 and switching part 324 are electrically connected to each other by way of the control logic circuit 326. The driving scheme for the organic EL devices 1A in the display part 310A is not restricted in particular, employable examples of which include DC driving, pulse driving, and AC driving. At the time of driving, a DC, pulsed, or AC current or voltage is preferably supplied, whereas the applied voltage is preferably on the order of 2 to 30 V.

Since the luminescent layers 20A contain a vinyl polymer having a side chain group including an anthracene structure and a hole-transferring compound having a glass transition temperature of at least 70° C., the above-mentioned embodiment can yield blue emission having a high color purity in luminous regions with a high luminance and high efficiency, and can stably keep this characteristic for a long period. This blue emission is taken out as it is from the substrate 1 side in the blue-emitting region. In the green- and red-emitting regions, phosphors corresponding to green and red in the fluorescence conversion filter films are pumped with the blue emission acting as a pumping light energy line, whereby green light and blue light are taken out from the substrate 1 side. Therefore, this embodiment can realize an organic EL display which is excellent in luminance and color displaying functions while having a high heat resistance and a long life.

The first EL display in accordance with the present invention is not limited to the above-mentioned embodiment, but can be determined in view of the luminance, life, power consumption, cost, and the like required for the aimed display product. For example, though FIG. 3 shows a so-called passive driving organic EL display, the first organic EL display may be an active driving full-color display using a polysilicon TFT or the like.

When the first organic EL display is made as a full-color display, it displays full colors by forming three primary color luminescent devices of red, green, and blue (RGB). The full-color displaying scheme may be any of the above-mentioned color conversion, RGB three-color juxtaposition, white luminescence, and the like. The RGB three-color juxtaposition is a scheme in which RGB three-color luminescent devices are individually caused to emit light. The white luminescence is a scheme in which a three-color filter used in a liquid crystal display device or the like partly cuts wavelengths of white luminescence, so as to display full colors. The white luminescence and color conversion are not required to prepare three luminescent devices, and thus can simplify the forming of luminescent devices and can easily conform to a larger area.

By appropriately choosing luminous dopants to be added to the luminescent layer of the organic EL device, the first organic EL display can employ any of the color displaying schemes mentioned above. For example, the color conversion scheme can favorably be employed when the organic layer of the organic EL device is caused to contain a blue-emitting dopant so as to act as a luminescent layer. The RGB three-color juxtaposition scheme based on phosphorescence can favorably be employed when the luminescent layer of the organic EL device is caused to contain a phosphorescent dopant.

The second organic EL device, second manufacturing method, and second organic EL display in accordance with the present invention will now be explained.

First, the second organic EL device will be explained in detail.

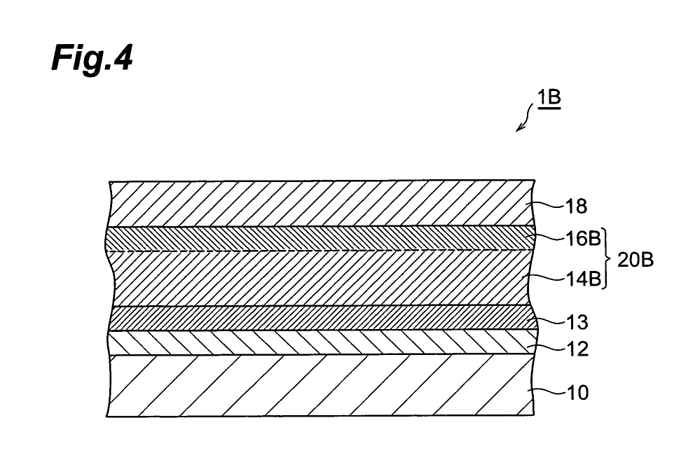

FIG. 4 is a schematic sectional view showing a preferred embodiment of the second organic EL device. The organic EL device 1B shown in FIG. 4 comprises a substrate 10, a first electrode layer (hole-injecting electrode layer) 12 formed on one side of the substrate 10, an electron-blocking layer 13 formed on the hole-injecting electrode layer 12, a luminescent layer 20B formed on the electron-blocking layer 13, and a second electrode layer (electron-injecting electrode layer) 18 formed on the luminescent layer 20B. As will be explained later, the electron-blocking layer 13 is an organic layer containing a hole-transferring compound having an electron affinity of 3.0 eV or less. The luminescent layer 20B, which is an organic layer containing a polymer having an anthracene structure, is constituted by a modified part 16B, formed near the surface on the electron-injecting electrode layer 18 side, containing a hole-blocking compound having a bandgap of at least 4.0 eV and the other part 14B.

The substrate 10, hole-injecting electrode layer 12, and electron-injecting electrode layer 18 in accordance with this embodiment are the same as the substrate 10, hole-injecting electrode layer 12, and electron-injecting electrode layer 18 in accordance with the embodiment of the first organic EL device, respectively, and thus will not be explained here.

Electron-Blocking Layer

The electron-blocking layer 13 is disposed between the hole-injecting electrode layer 12 and the luminescent layer 20B, and is constructed so as to contain a hole-transferring compound having an electron affinity of 3.0 eV or less.

The hole-transferring compound is not limited in particular as long as its ionization potential satisfies the condition mentioned above, whereas its examples include low-molecular hole-transferring compounds such as those of triphenylamine, pyrazoline, arylamine, and stilbene structures, and polymer compounds having structures derived from these low-molecular compounds.

Preferred among them as a material of the electron-blocking layer 13 are polymer compounds having a triphenylamine structure represented by the above-mentioned general formula (5), and more preferred are polymer compounds having a triphenyldiamine structure. The number average molecular weight of such a polymer compound is preferably 5,000 to 1,000,000, more preferably 20,000 to 100,000.

In the polymer compounds having a triphenylamine structure, the triphenylamine structure may be contained in either the main or side chain of the polymer compounds. Preferred examples of the polymer compounds include those having a structure unit represented by the above-mentioned general formula (5-a) or (5-b).

The following Table 12 shows specific examples of the structure unit in the hole-transferring polymer compounds represented by the above-mentioned general formula (5-a) or (5-b). Each of the polymer compounds shown in Table 12 has an electron affinity of 3.0 eV or less. For example, TPD-PES having the structure unit (5-a-1) has an ionization potential of 2.4 eV. The triphenylene amine structure of the polymer compound in the second organic EL device is not restricted in particular as long as the polymer compound has an electron affinity of 3.0 eV or less, and may have any of structures corresponding to specific examples of triphenylamine derivatives which will be exemplified in the explanation of the luminescent layer as well as the structures shown in the following Table 12.

TABLE 12

| | |
|---|---|
| No. | 5-a-1 |
| Structure unit | 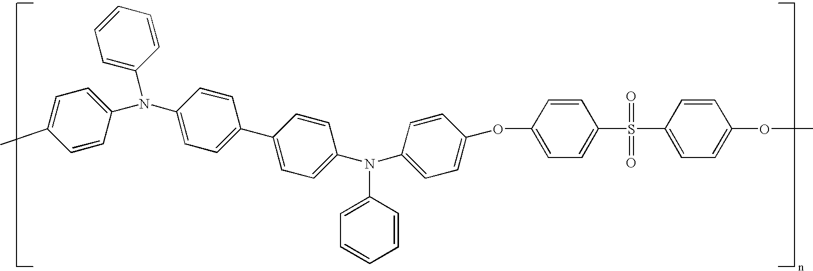 |
| No. | 5-a-2 |
| Structure unit | 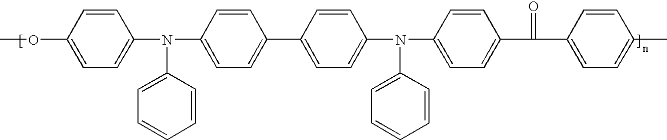 |
| No. | 5-b-1 |
| Structure unit | 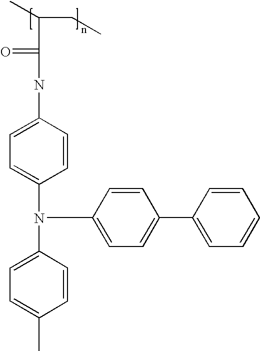 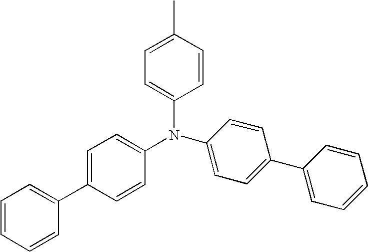 |

From the viewpoint of effectively yielding an electron-blocking property and a favorable coatability, the thickness of the electron-blocking layer 13 is preferably 5 to 200 nm, more preferably 20 to 100 nm.

Luminescent Layer

As mentioned above, the luminescent layer 20B is an organic layer containing a polymer having an anthracene structure. The luminescent layer 20B is constituted by the modified part 16B, formed near the surface on the electron-injecting electrode layer 18 side, containing a hole-blocking compound having a bandgap of at least 4.0 eV and the other part 14B.

The vinyl polymer having an anthracene structure contained in the luminescent layer 20B is the same as the vinyl polymer having an anthracene structure contained in the luminescent layer 20A in the embodiment of the first organic EL device, and thus will not be explained here.

From the viewpoint of elongating the life of the organic EL device, the content of the polymer having an anthracene structure is preferably 30 to 99 mass %, more preferably 50 to 90 mass %, based on the total amount of constituent materials of the luminescent layer 20B.

The luminescent layer 20B may further contain polymers other than the polymer having the anthracene structure. However, on the basis of the total amount of the polymer having the anthracene structure and the other polymers, the content of the former polymer is preferably at least 50 mass %, more preferably at least 80 mass %, for achieving a longer life.

Preferably, the luminescent layer 20B further contains a hole-transferring compound. The molecular weight of the hole-transferring compound is not restricted in particular as long as it can be dispersed and held within the polymer having the anthracene structure, but is preferably at least 400.

The glass transition temperature of the hole-transferring compound is preferably at least 70° C., more preferably at least 100° C. Using a hole-transferring compound whose glass transition temperature satisfies the condition mentioned above can further improve device characteristics such as luminance and luminous efficiency, and can keep these characteristics for a long period.

Specific employable examples of the hole-transferring compound include triphenylamine derivatives, pyrazoline derivatives, arylamine derivatives, and stilbene derivatives, among which triphenylamine derivatives are preferred.

The triphenylamine derivative contained in the luminescent layer 20B is the same as the triphenylamine derivative contained in the luminescent layer 20A in accordance with the embodiment of the first organic EL device, and thus will not be explained here.

The polymer compound having the triphenylamine structure exemplified in the explanation of the electron-blocking layer 13 may be contained as a hole-transferring compound in the luminescent layer.

From the viewpoint of elongating the life of the organic EL device, the content of the hole-transferring compound in the luminescent layer 20B is preferably 50 mass % or less, more preferably 10 to 40 mass %, on the basis of the total amount of constituent materials in the luminescent layer 20B.

Also from the viewpoint of elongating the life of the organic EL device, the ratio between the polymer having an anthracene structure and the hole-transferring compound is such that the latter is preferably 50 parts or less, more preferably 10 to 40 parts, with respect to 100 parts of the former in terms of mass ratio.

In the luminescent layer 20B, the polymer having the anthracene structure functions as a host material, whereby doping it with a luminous dopant as a guest material can yield a desirable emission color. For example, iridium complexes such as tris(2-phenylpyridine)iridium (Ir(Ppy)₃) and platinum complexes having a porphyrin ring such as 2,3,7,8,12,13,17,18-octaethyl-21H,23H-porphyrin platinum (PtOEP) can be used as a phosphorescent dopant. On the other hand, tetraphenyl butadiene and its derivatives, styrylamine derivatives, fluoranthene derivatives, and the like can be used as a blue-emitting dopant. The ratio of the luminous dopant is preferably 1 to 30 mass % with respect to the total amount of polymerizable monomers before polymerization.

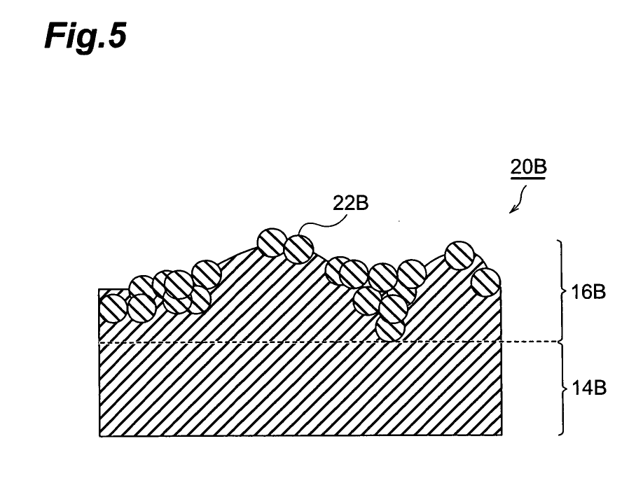

The modified part 16B of the luminescent layer 20B is constructed so as to contain a hole-blocking compound having a bandgap of at least 4.0 eV. FIG. 5 is an explanatory view schematically showing an example of the state of the luminescent layer 20B having the modified part 16B near the surface on the electron-injecting electrode layer 18 side. In FIG. 5, particles 22B of the hole-blocking compound having a bandgap of at least 4.0 eV exist at all the positions in the thickness direction of the modified part 16B. In the part 14B other than the modified part 16B, on the other hand, no particles 22B of the hole-blocking compound having a bandgap of at least 4.0 eV exist at any position in the thickness direction.

Also, as shown in FIG. 5, the surface of the luminescent layer 20B has a certain degree of irregularities since it contains a polymer. When forming the luminescent layer 20B by a coating method, particles 22B of the carrier-blocking compound seem to exist in a so-called infiltrated state, thereby forming the modified part 16B. Since the surface of the luminescent layer 20B has irregularities, the adhesion of particles 22B of the hole-blocking compound having a bandgap of at least 4.0 eV to the luminescent layer 20B increases drastically, whereby the particles 22B of hole-blocking compound having a bandgap of at least 4.0 eV are harder to peel off once the modified part 16B is formed. It seems that the polymer compound existing near such an irregular surface can relatively easily form the modified part 16B with a concentration gradient such as that mentioned above, thereby effectively contributing to recombination between holes and electrons in the luminescent layer. The luminous efficiency and life of the organic EL device are assumed to improve because of the foregoing.

As the hole-blocking compound having a bandgap of at least 4.0 eV contained in the modified part 16B, the polymer compounds and organic metal compounds having a bandgap of at least 4.0 eV exemplified in the explanation of the modified part 16A in accordance with the embodiment of the first organic EL device can favorably be used. These polymer compounds and organic metal compounds will not be explained here in detail.

The modified part 16B in the luminescent layer 20B can favorably be formed by coating with a solution containing a hole-blocking compound having a bandgap of at least 4.0 eV. Any solvent can be used in such a solution without being restricted in particular, as long as it can dissolve the hole-blocking compound. A polar solvent is preferably used from the viewpoint of coatability, solubility, and the like. When a nonpolar solvent is used, a desirable modified part 16B may be harder to form depending on compounds used for coating. Examples of the polar solvent include 2-methoxyethanol, isopropyl cellosolve, methyl lactate, ethyl acetate, acetoin, diacectone alcohol, 4-hydroxybutanone, propioin, 2-hydroxy-2-methyl-3-butanone, dimethylformamide, dimethylacetamide, propyl acetate, butyl acetate, sec-butyl acetate, tert-butyl acetate, pentyl acetate, 2-methylbutyl acetate, 3-methylbutyl acetate, hexyl acetate, heptyl acetate, ethyl butyrate, ethyl isobutyrate, propyl butyrate, isopropyl butyrate, propyl propionate, methyl valerate, methyl isovalerate, ethyl valerate, ethyl isovalerate, ethylmethyl carbonate, diethyl carbonate, dipropyl carbonate, N,N-dimethylacetamide, and 2-ethoxyethanol, among which 2-ethoxyethanol is used more preferably.

In the modified part 16B, the thickness of the hole-blocking compound having a bandgap of at least 4.0 eV contained therein is preferably 5.0×10⁻⁹ to 1.0×10⁻⁶ g/cm², more preferably 2.5×10⁻⁸ to 5.0×10⁻⁷ g/cm². Since the modified part 16B contains a hole-blocking compound having such a thickness, the organic EL device can effectively improve the luminous efficiency and attain a sufficiently long life. When the thickness of the hole-blocking compound exceeds 1.0×10⁻⁶ g/cm², electrons are harder to pass through the modified part 16B, thus making it more difficult for the organic EL device 1B to emit light.

The thickness of the hole-blocking compound having a bandgap of at least 4.0 eV can be adjusted by appropriately regulating various conditions under which the modified part 16B is formed. When forming the modified part 16B by the above-mentioned coating, for example, the thickness can be adjusted by regulating the concentration of the hole-blocking compound in the coating solution, coating time, amount of the coating solution, etc.

The method of carrying out the coating (coating method) is not restricted in particular. For example, spin coating, spray coating, dip-coating, ink jetting, and printing can be employed.

The thickness of the luminescent layer 20B is not restricted in particular and varies depending on the forming method. From the viewpoint of further improving the luminous efficiency, the thickness is preferably 20 to 150 nm.

Though a preferred embodiment of the second organic EL device is explained in the foregoing, the present invention is not limited to the above-mentioned embodiment. For example, though the hole-injecting electrode layer 12 side is employed as the light exit side in the above-mentioned embodiment, the electron-injecting electrode layer, luminescent layer, and hole-injecting electrode layer may be laminated successively from the substrate, so that the electron-injecting electrode layer side is used as the light exit side. In this case, it will be preferred if the electron-injecting electrode layer satisfies the optical and thickness conditions in the case where the hole-injecting electrode layer is employed as the light exit side.

Though the above-mentioned embodiment includes only one luminescent layer, the luminescent layer in the second organic EL device may have a multilayer structure in which a plurality of luminescent layers are laminated. The organic EL device may further comprise a hole-injecting layer, a hole-transferring layer, an electron-transferring layer, and the like in addition to the luminescent layer. In this case, the hole-injecting layer may be laminated adjacent to the hole-injecting electrode layer on the luminescent layer side, the hole-transferring layer may be laminated between the hole-injecting layer and the luminescent layer, and the electron-transferring layer may be laminated between the electron-injecting electrode layer and the luminescent layer.

Examples of the hole-transferring material used in the hole-transferring layer and the electron-transferring material used in the electron-transferring layer include those mentioned above. Examples of the hole-injecting material used in the hole-injecting layer include known conductive polymer compounds such as polythiophene and polyaniline.

When forming the above-mentioned organic layers by such a coating method, the thickness per species of organic layer is preferably 0.5 to 1,000 nm, more preferably 10 to 500 nm. When the thickness of the organic layers is large, at least 20 nm in particular, leak currents can be prevented from occurring.

Preferably, for preventing the organic layers and electrodes in the device from deteriorating, the upper side of the device is sealed with a sealing plate or the like. For preventing moisture from entering, an adhesive resin layer is used for bonding and tightly sealing the sealing plate. The sealing gas is preferably an inert gas such as Ar, He, or N₂, etc. The moisture content in the sealing gas is preferably 100 mass ppm or less, more preferably 10 mass ppm or less, 1 mass ppm or less in particular. Though the moisture content has no lower limit in particular, the lower limit is usually about 0.1 mass ppm.

A preferred embodiment of the second manufacturing method will now be explained in detail. Here, a method of manufacturing the second organic EL device configured as shown in FIG. 4 will be explained.

First, on a substrate 10 prepared, a hole-injecting electrode layer 12 such as ITO is formed. As its forming method, a conventionally used method such as sputtering or vapor deposition can be employed.

Subsequently, an electron-blocking layer 13 is formed on the hole-injecting electrode layer 12. When using a hole-transferring polymer compound or the like having an electron affinity of 3.0 eV or less as a constituent material of the electron-blocking layer 13, a solution in which the polymer is added to a predetermined solvent is applied onto the hole-injecting electrode layer 12, whereby the electron-blocking layer 13 can be formed. As the coating method, spin coating, spray coating, dip-coating, ink jetting, printing, or the like can be employed.

Next, a luminescent layer 20B is formed on the electron-blocking layer 13. As its forming method, a coating method such as spin coating, spray coating, dip-coating, ink jetting, or printing can be employed.

Subsequently, for forming a modified part 16B near the surface of the luminescent layer 20B, a solution in which such a hole-blocking compound as that mentioned above is added to a predetermined solvent (which is preferably a polar solvent) is applied to the surface of the luminescent layer 20B. The coating method is not restricted in particular, whereby spin coating, spray coating, dip-coating, ink jetting, or printing, for example, can be employed.

Preferably, the concentration of the nonluminous polymer in the solution is adjusted such that the modified part 16B attains a desirable thickness. For example, the concentration is preferably 0.01 to 1.0 mass % when coating is performed by spin coating. This range indicates a concentration much lower than that of the solution used when forming an organic layer containing a polymer compound in the conventional organic EL device by a coating method. Coating with a solution having such a concentration tends to be able to provide the modified part 16B with an appropriate concentration gradient.

Then, an electron-injecting electrode layer 18 is formed on the luminescent layer 20B, so as to complete the organic EL device 1B. As its forming method, a conventionally used method such as vapor deposition or sputtering can be employed.

For forming an interface between two organic layers when manufacturing an organic EL device in which a plurality of organic layers are laminated, it will be sufficient if the coating surface of the lower layer is dried to form a film, and then an upper layer is applied thereto. In this case, heating or the like may be carried out if necessary after applying the lower layer.

When no interface is formed between two organic layers, the boundary of the two layers may be formed so as to yield a so-called slanted composition. Namely, coating with materials which differ from each other in at least one of the solubility to the solvent, solvent, viscosity, and specific gravity can apply two species of organic layers differently and change the boundary composition like a slope. Before drying the coating surface of the lower layer, the next layer may be applied thereto, so that no interface is formed.

The second organic EL display will now be explained.

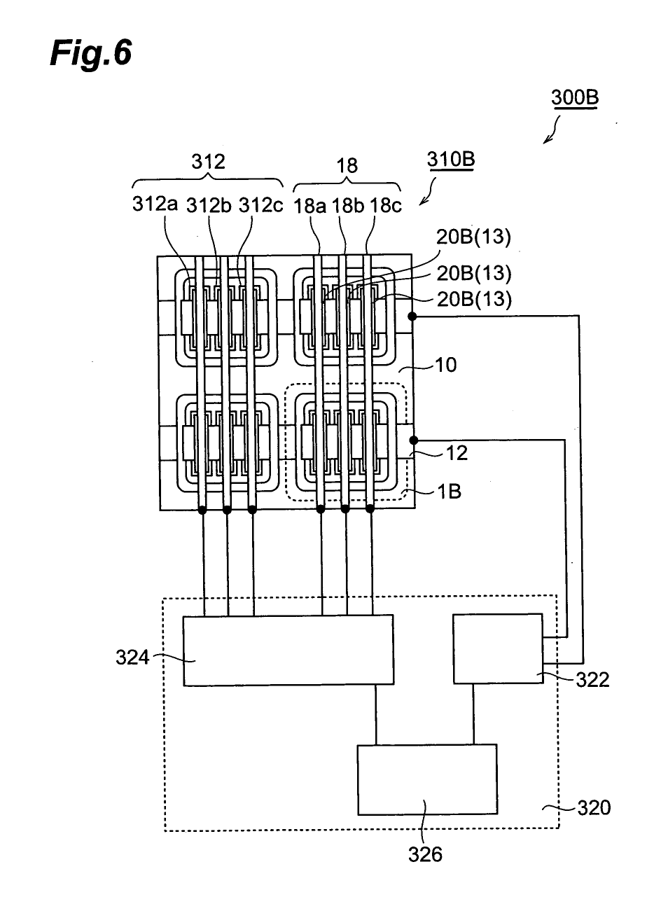

FIG. 6 is a block diagram showing a preferred embodiment of the second organic EL display. The organic EL display 300B shown in FIG. 6 is a passive driving organic EL display of color conversion type using a blue-emitting device as a pumping light source. The color conversion is a method in which fluorescent elements for three colors are pumped with visible light emission of a high-energy line. The color conversion typically generates blue emission in an organic layer of the organic EL device, and pumps green and red fluorescent surfaces with the blue emission as a pumping light energy line, so as to yield green light and red light. This scheme is known as color conversion, since blue is converted into green and red.

In FIG. 6, a display part 310B is one in which a plurality of organic EL devices 1B, each constituted by a substrate 10, a hole-injecting electrode layer 12 formed on one side of the substrate 10, electron-blocking layers 13 formed on the hole-injecting electrode layer 12, luminescent layers 20B formed on the electron-blocking layers 13, and an electron-injecting layer 18 formed on the luminescent layers 20B, are arranged two-dimensionally. In each of the organic EL devices 1B, three luminescent layers 20B, each containing a polymer having an anthracene structure and a blue-emitting dopant while having a modified part 16B near the surface on the electron-injecting electrode layer 18 side, are formed so as to correspond to three luminous regions 312 (e.g., 312a, 312b, 312c). In the three luminous regions 312a to 312c, one is a blue-emitting region, whereas the remaining two are green- and red-emitting regions, respectively.

Preferred examples of the material of the substrate 10 include transparent or semitransparent materials such as glass, silica, and resin.

On the substrate 10, respective regions corresponding to two of the three luminous regions formed in one organic EL device are provided with fluorescence conversion filter films as mentioned above, so as to become green- and red-emitting regions, respectively, as their emission colors are controlled by the fluorescence conversion filter films. The luminous region provided with no fluorescence conversion filter film is the blue-emitting region.

Each fluorescence conversion filter film, which absorbs light generated by electroluminescence in the luminous layer 20B and causes a phosphor in the film to emit light in a color different from that of the absorbed light so as to convert the emission color into another color, is typically constructed so as to contain the phosphor, a light absorber, and a binder. The fluorescence conversion filter film can be formed by patterning utilizing a technique such as photolithography or printing. Preferably, in this case, the material of the fluorescence conversion filter material is capable of forming a fine patterning and less likely to be damaged in the step of forming the upper layer (e.g., hole-injecting electrode layer 12).

Preferably, the phosphor contained in the fluorescence conversion filter film has a high fluorescent quantum efficiency and exhibits a high light absorption in the emission wavelength range of the luminescent device as with a laser dye. Examples of such a phosphor include rhodamine-based compounds, perylene-based compounds, cyanine-based compounds, phthalocyanine-based compounds such as subphthalocyanine, naphthalimide-based compounds, condensed-ring-hydrocarbon-based compounds, condensed heterocyclic compounds, styryl-based compounds, and coumarin-based compounds. When the light absorption of the phosphor itself is insufficient, a light absorber is preferably used therewith, whereas one which does not extinguish the fluorescence is preferred as the light absorber.

The binder is not restricted in particular as long as it does not extinguish the fluorescence, and can appropriately be chosen for use from among known binders.

Preferably, a color filter which cuts off external light having a short wavelength absorbable by constituent materials of the organic EL device 1B and the fluorescence conversion filter film is combined with the fluorescence conversion filter film, since the light resistance and display contrast of the device are further improved thereby.

In the display part 310B, two hole-injecting electrode layers 12 are formed in parallel on the substrate 1 and fluorescence conversion filter film so as to pass the three luminous regions 312a to 312c in each organic EL device 1B. Here, each hole-injecting electrode layer 12 is arranged so as to partly expose each of the luminous regions 312a to 312c without completely covering them. Each hole-injecting electrode layer 12 is a common electrode for a plurality of (two in FIG. 6) organic EL devices, whereas a power supply part 322 which will be explained later is electrically connected to one end each of the hole-injecting electrode layers 12. Such a stripe-like hole-injecting electrode layer 12 can be formed, for example, by forming an ITO film on the substrate 10 having the fluorescence conversion filter film patterned thereon, and then carrying out patterning and etching.

Though not depicted in detail, after forming the hole-injecting electrode layer 12, an insulator layer such as SiO₂ layer or Al₂O₃ layer is preferably provided thereon. Then, preferably, regions of the insulator layer corresponding to the luminous regions are opened by etching or the like, and luminescent layers 20B are formed in these openings.

In the display part 310B, the luminescent layers 20B are formed so as to cover their corresponding luminous regions in the organic EL devices 1B while riding over the hole-injecting electrode layers 12. The luminescent layers 20B can favorably be formed by a coating method such as spin coating. Heating the coating liquid can reduce the residual solvent, thereby achieving a high adhesion between each of the luminescent layers 20B to each of the hole-injecting electrode layers 12 and electron-injecting electrode layers 18.

In the display part 310B, six electron-injecting electrode layers 18 are formed so as to pass over the luminescent layers 20B while corresponding to the luminous regions of the organic EL devices 1B. Each of the electron-injecting electrode layers 18 is a common electrode for a plurality of (two in FIG. 6) organic EL devices 1A, whereas a switching part 324 which will be explained later is connected to one end each of the electron-injecting electrode layers 18.

In a passive driving organic EL device as with this embodiment, it will be preferred if the stripe-like hole-injecting electrode layers 12 and stripe-like electron-injecting electrode layers 18 are arranged such that their extending directions are orthogonal to each other as shown in FIG. 6. Here, each intersection between the extending direction of the hole-injecting electrode layer 12 and the electron-injecting electrode layer 18 in each luminous region corresponds to one pixel of the display.

In the nonluminous region of the display part 310B, a spacer 314 is provided for each organic EL device 1B. Attaching a sealing plate (not depicted) to the spacer 314 seals the surface on the electron-injecting electrode layer 18 side.

In the organic EL display 300B, a driving part 320 for controlling the display in the display part 310B is constructed so as to include the power supply part 322 for supplying a current or voltage to the hole-injecting layers 12 and electron-injecting electrode layers 18, the switching part 324 for sending an on/off control signal to the organic EL device 1B, and their control logic circuit 326. The power supply part 322 is electrically connected to the hole-injecting electrode layers 12, whereas the switching part 324 is electrically connected to electron-injecting electrode layers 18. The power supply part 322 and switching part 324 are electrically connected to each other by way of the control logic circuit 326. The driving scheme for the organic EL devices 1B in the display part 310B is not restricted in particular, employable examples of which include DC driving, pulse driving, and AC driving. At the time of driving, a DC, pulsed, or AC current or voltage is preferably supplied, whereas the applied voltage is preferably on the order of 2 to 30 V.

By causing the luminescent layers 20B to contain a polymer including an anthracene structure, modifying the vicinity of the surface of the luminescent layer 20B on the electron-injecting electrode layer 18 side with the specific hole-blocking compound mentioned above, and providing the electron-blocking layers 13 containing a specific hole-transferring compound between the hole-injecting electrode layers 12 and luminescent layers 20B, the above-mentioned embodiment can yield blue emission having a high color purity in luminous regions with a high luminance and high efficiency, and can stably keep this characteristic for a long period. This blue emission is taken out as it is from the substrate 1 side in the blue-emitting region. In the green- and red-emitting regions, phosphors corresponding to green and red in the fluorescence conversion filter films are pumped with the blue emission acting as a pumping light energy line, whereby green light and blue light are taken out from the substrate 1 side. Therefore, this embodiment can realize an organic EL display which is excellent in luminance and color displaying functions while having a high heat resistance and a long life.

The second organic EL display is not limited to the above-mentioned embodiment, but can be determined in view of the luminance, life, power consumption, cost, and the like required for the aimed display product. For example, though FIG. 6 shows a so-called passive driving organic EL display, the second organic EL display may be an active driving full-color display using a polysilicon TFT or the like.

When the second organic EL display is made as a full-color display, it displays full colors by forming three primary color luminescent devices of red, green, and blue (RGB). The full-color displaying scheme may be any of the above-mentioned color conversion, RGB three-color juxtaposition, white luminescence, and the like. The RGB three-color juxtaposition is a scheme in which RGB three-color luminescent devices are individually caused to emit light. The white luminescence is a scheme in which a three-color filter used in a liquid crystal display device or the like partly cuts wavelengths of white luminescence, so as to display full colors. The white luminescence and color conversion are not required to prepare three luminescent devices, and thus can simplify the forming of luminescent devices and can easily achieve a larger area.

By appropriately choosing luminous dopants to be added to the luminescent layer of the organic EL device, the second organic EL display can employ any of the color displaying schemes mentioned above. For example, the color conversion scheme can favorably be employed when the organic layer of the organic EL device is caused to contain a blue-emitting dopant so as to act as a luminescent layer. The RGB three-color juxtaposition scheme based on phosphorescence can favorably be employed when the luminescent layer of the organic EL device is caused to contain a phosphorescent dopant.

### EXAMPLES

In the following, the present invention will be explained more specifically with reference to examples and comparative examples, though the following examples do not restrict the present invention at all.

### Example 1

First, as a hole-injecting electrode (anode) layer, a substrate made of transparent glass formed with an ITO film having a sheet resistance of 15 Ω/□ was prepared, and polyethylenedioxythiophene/polystyrenesulfonate (PEDOT/PSS; Baytron P manufactured by Bayer AG) was applied onto the ITO film by spin coating, so as to form a hole-injecting layer having a thickness of 50 nm.

Subsequently, 80 mass % of a vinyl polymer (homopolymer with a number average molecular weight of 30,000) having the structure unit (1-3) in the above-mentioned Table 1, 15 mass % of the triphenyldiamine derivative (having a glass transition temperature of 98° C.) represented by the formula (5-1) in the above-mentioned Table 8, and 5 mass % of rubrene as a luminous dopant were dissolved in toluene so as to yield a concentration of 2 mass % in total. This solution was applied onto the hole-injecting layer by spin coating, so as to yield a luminescent layer having a thickness of 70 nm.

Further, poly(2-vinylpyridine) (having a number average molecular weight of 300,000) was dissolved in 2-ethoxyethanol so as to prepare a 0.1 mass % solution. This solution was applied onto the luminescent layer by spin coating, and was dried (annealed) in an N₂ atmosphere at 180° C. for 1 hour, so as to form a modified part.

Then, LiF was vapor-deposited so as to yield a thickness of 0.2 nm on the luminescent layer formed with the modified part, and Al was vapor-deposited thereon so as to yield a thickness of 250 nm, thus forming an electron-injecting electrode (cathode) layer, whereby an organic EL device of Example 1 was obtained.

When thus obtained organic EL device was driven with a constant current from an initial luminance of 600 cd/m², the time required for the luminance to decrease by half (hereinafter referred to as “luminance half life”) was 1,500 hours.

### Example 2

An organic EL device was made as in Example 1 except that no annealing was performed when forming the modified part.

When thus obtained organic EL device was driven with a constant current from an initial luminance of 600 cd/m², the luminance half life was 250 hours.

### Example 3

An organic EL device was made as in Example 1 except that a triphenyldiamine derivative (having a glass transition temperature of 83° C.) represented by the formula (5-2) in the above-mentioned Table 8 was used in place of the triphenyldiamine derivative represented by the formula (5-1) in the above-mentioned Table 8.

When thus obtained organic EL device was driven with a constant current from an initial luminance of 600 cd/m², the luminance half life was 530 hours.

### Example 4

An organic EL device was made as in Example 1 except that a vinyl polymer (with a glass transition temperature of 190° C.) having a triphenyldiamine structure represented by the following formula (6) was used in place of the triphenyldiamine derivative represented by the formula (5-1) in the above-mentioned Table 8. 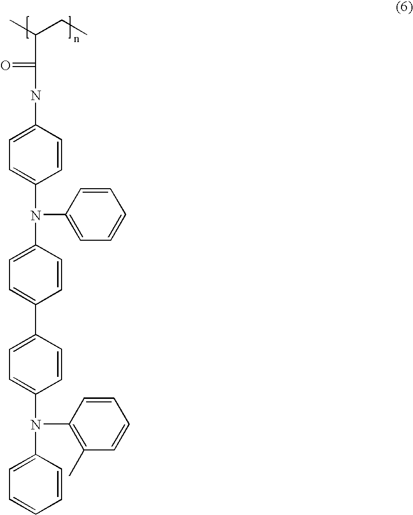
where n is an integer of at least 1.

When thus obtained organic EL device was driven with a constant current from an initial luminance of 600 cd/m², the luminance half life was 580 hours.

### Example 5

An organic EL device was made as in Example 1 except that a polymer having a triphenyldiamine structure represented by the following formula (7) was used in place of the vinyl polymer having the structure unit (1-3) in the above-mentioned Table 1.

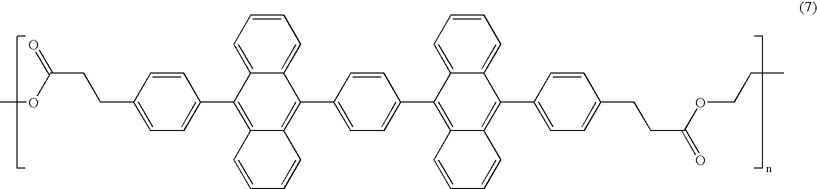

### Comparative Example 1

First, a hole-injecting electrode layer and a hole-injecting layer were formed as in Example 1.

Subsequently, 95 mass % of a vinyl polymer (with a number average molecular weight of 30,000) having the structure unit (1-3) in the above-mentioned Table 1 and 5 mass % of rubrene as a luminous dopant were dissolved in toluene so as to yield a concentration of 2 mass % in total. This solution was applied onto the hole-injecting layer by spin coating, so as to yield a luminescent layer having a thickness of 70 nm.

Further, a modified part in the luminescent layer and an electron-injecting electrode layer were formed as in Example 1, so as to yield an organic EL device of Comparative Example 1.

When thus obtained organic EL device was driven with a constant current from an initial luminance of 600 cd/m², the luminance half life was 130 hours.

### Comparative Example 2

An organic EL device was made as in Example 1 except that a triphenyldiamine derivative (having a glass transition temperature of 66° C.) represented by the following formula (8) was used in place of the triphenyldiamine derivative represented by the formula (5-1) in the above-mentioned Table 8.

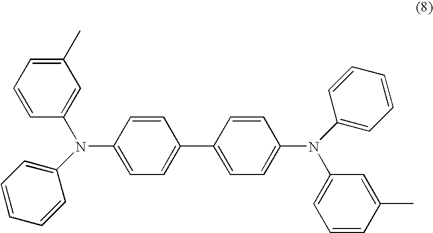

When thus obtained organic EL device was driven with a constant current from an initial luminance of 600 cd/m², the luminance half life was 3 hours.

### Comparative Example 3

An organic EL device was made as in Comparative Example 2 except that no annealing was performed when forming the modified part.

When thus obtained organic EL device was driven with a constant current from an initial luminance of 600 cd/m², the luminance half life was 30 hours.

### Comparative Example 4

Making of an organic EL device was attempted as in Example 1 except that an anthracene low-molecular material represented by the following formula (9) was used in place of the vinyl polymer having the structure unit (1-3) in the above-mentioned Table 1. However, the luminescent layer was completely dissolved when modifying (coating) the luminescent layer, thus failing to yield the aimed organic EL device.

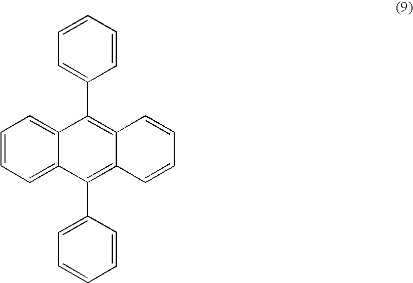

### Comparative Example 5

An organic EL device was made as in Example 1 except that polyvinylcarbazole (PVK; with a number average molecular weight of 300,000) was used in place of the vinyl polymer having the repeating unit represented by the above-mentioned formula (8), so as to make an organic EL device.

When thus obtained organic EL device was driven with a constant current from an initial luminance of 600 cd/m², the luminance half life was 10 minutes.

### Example 6

First, as a hole-injecting electrode (anode) layer, a substrate made of transparent glass formed with an ITO film having a sheet resistance of 15 Ω/□ was prepared, and polyethylenedioxythiophene/polystyrenesulfonate (PEDOT/PSS; Baytron P manufactured by Bayer AG) was applied onto the ITO film by spin coating, so as to form a hole-injecting layer having a thickness of 50 nm.

Subsequently, a polymer compound (TPD-PES having a number average molecular weight of 20,000) was dissolved in dichloroethane, so as to prepare a 1.5 mass % solution, and thus obtained solution was applied onto the hole-injecting layer by spin coating, whereby an electron-blocking layer having a thickness of 20 nm was formed.

Next, 80 mass % of a vinyl polymer (homopolymer with a number average molecular weight of 30,000) having the structure unit (1-3) in the above-mentioned Table 1, 15 mass % of the triphenyldiamine derivative (having a glass transition temperature of 98° C.) represented by the formula (5-1) in the above-mentioned Table 8, and 5 mass % of rubrene as a luminous dopant were dissolved in toluene so as to yield a concentration of 2 mass % in total. This solution was applied onto the electron-injecting layer by spin coating, so as to yield a luminescent layer having a thickness of 70 nm.

Further, poly(2-vinylpyridine) (having a number average molecular weight of 300,000) was dissolved in 2-ethoxyethanol so as to prepare a 0.1 mass % solution. This solution was applied onto the luminescent layer by spin coating, and was dried (annealed) in an N₂ atmosphere at 180° C. for 1 hour, so as to form a modified part.

Then, LiF was vapor-deposited so as to yield a thickness of 0.2 nm on the luminescent layer formed with the modified part, and Al was vapor-deposited thereon so as to yield a thickness of 250 nm, thus forming an electron-injecting electrode (cathode) layer, whereby an organic EL device of Example 6 was obtained.

When thus obtained organic EL device was driven with a constant current from an initial luminance of 1,000 cd/m² at an initial voltage of 6.5 V and a current density of 20 mA/cm², the time required for the luminance to decrease by half (hereinafter referred to as “luminance half life”) was 1,800 hours.

### Example 7

A mixture was formed by 95 mass % of vinyl polymer having the structure unit (4-8) in the above-mentioned Table 7 and 5 mass % of rubrene, and was dissolved in toluene such as to yield a total concentration of 2 mass %. An organic EL device was made as in Example 6 except that this coating liquid was used.

When thus obtained organic EL device was driven with a constant current from an initial luminance of 1,000 cd/m² at an initial voltage of 6.8 V and a current density of 28 mA/cm², the luminance half life was 500 hours.

### Comparative Example 6

A hole-injecting electrode layer, an electron-blocking layer, a luminescent layer having a modified part, and an electron-injecting electrode layer were successively formed on a substrate as in Example 1 except that polyvinylcarbazole (PVK; with a number average molecular weight of 300,000) was used in place of the vinyl polymer having the structure unit (1-3) in the above-mentioned Table 1, so as to yield an organic EL device.

Thus obtained organic EL device emitted light at the maximum of 770 cd/m² (22 V, 1,200 mA/cm²).

What is claimed is:

1. An organic EL device comprising:
a pair of electrodes disposed so as to oppose each other; and
a luminescent layer, disposed between the electrodes, containing a polymer having an anthracene structure and a hole-transferring compound having a glass transition temperature of at least 70° C.

2. An organic EL device according to claim 1, wherein the luminescent layer is formed by a coating method using a coating liquid containing the polymer and hole-transferring compound.

3. An organic EL device according to claim 2, wherein the luminescent layer is annealed.

4. An organic EL device according to claim 1, wherein the polymer contains at least one species of structure units represented by the following general formulas (1) to (4): 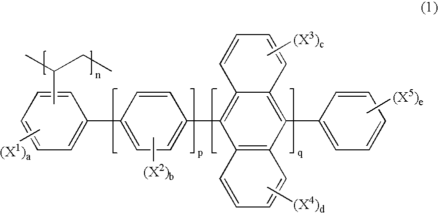
where X¹, X², X³, X⁴, and X⁵ are either identical or different from each other, each representing an alkyl group, alkoxy group, aryl group, aryloxy group, heterocyclic group, halogen atom, cyano group, hydroxyl group, or amino group; a, b, c, and d are integers of 0 to 4; e is an integer of 0 to 5; p is 0 or 1; and q is an integer of 1 to 3; 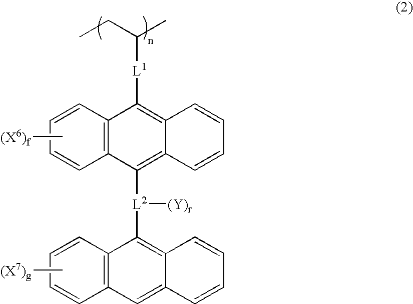
where L¹ is a bivalent organic group; L² is a bivalent aliphatic hydrocarbon group with a carbon number of 1 to 4, an aromatic group having a valence of (r+2) with a carbon number of 6 to 13, or an imino group; Y, X⁶, and X⁷ are independently univalent substituents; f is an integer of 0 to 8; g is an integer of 0 to 9; r is an integer of 0 or 1; and n is an integer of at least 1; 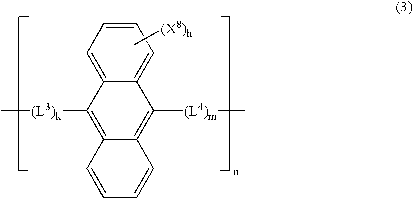
where L³ and L⁴ are bivalent organic groups; X⁸ is an alkyl group, alkoxy group, aryl group, aryloxy group, heterocyclic group, halogen atom, cyano group, hydroxyl group, or amino group; h is an integer of 0 to 8; k and m are each 0 or 1, while (k+m) is at least 1; and n is an integer of at least 1; and 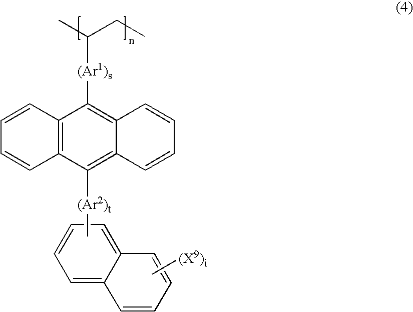
where Ar¹ and Ar² are either identical or different from each other, each representing a substituted or unsubstituted phenylene group or substituted or unsubstituted naphthylene group; X⁹ is an alkyl group, alkoxy group, aryl group, aryloxy group, heterocyclic group, halogen atom, cyano group, hydroxyl group, or amino group; s is 1 or 2; t is 0 or 1; i is an integer of 0 to 7; and n is an integer of at least 1.

5. An organic EL device according to claim 1, wherein the hole-transferring compound has a triphenylamine structure.

6. An organic EL device according to claim 1, wherein the luminescent layer has a modified part containing a hole-blocking compound having an ionization potential of at least 5.5 eV near a surface on the side closer to an electron-injecting electrode in the pair of electrodes.

7. An organic EL device according to claim 1, wherein the hole-blocking compound is at least one species selected from polymer compounds and organic metal compounds having a bandgap of at least 4.0 eV.

8. A method of manufacturing an organic EL device comprising a pair of electrodes disposed so as to oppose each other and a luminescent layer, disposed between the electrodes, containing a polymer having an anthracene structure and a hole-transferring compound having a glass transition temperature of at least 70° C.;
the method comprising the step of forming the luminescent layer by a coating method using a coating liquid containing the polymer and hole-transferring compound.

9. A method of manufacturing an organic EL device according to claim 8, further comprising the step of annealing the luminescent layer formed by the coating method.

10. An organic EL display comprising:
a display part having a plurality of organic EL devices arranged therein, each organic EL device comprising a pair of electrodes disposed so as to oppose each other and a luminescent layer, disposed between the electrodes, containing a polymer having an anthracene structure and a hole-transferring compound having a glass transition temperature of at least 70° C.;
a power supply part, electrically connected to each of the pair of electrodes, for supplying a voltage or current to the electrodes; and
a switching part for turning on/off the organic EL devices.

11. An organic EL device comprising:
a hole injection electrode and an electron injection electrode disposed so as to oppose each other;
a luminescent layer, disposed between the hole injection electrode and electron injection electrode, containing a polymer having an anthracene structure and a modified part, disposed near a surface on the side closer to the electron injection electrode, containing a hole-blocking compound having a bandgap of at least 4.0 eV; and
an electron-blocking layer, disposed between the hole injection electrode and luminescent layer, containing a hole-transferring compound having an electron affinity of 3.0 eV or less.

12. An organic EL device according to claim 11, wherein the luminescent layer is obtained by forming a coating by a coating method using a coating liquid containing the polymer and then forming the modified part by applying a coating liquid containing the hole-blocking compound onto a surface of the coating on the side closer to the electron injection electrode.

13. An organic EL device according to claim 11, wherein the modified region is formed in a region distanced by 0.1 to 10 nm from the surface of the luminescent layer on the side closer to the electron injection electrode in the depth direction of the luminescent layer.

14. An organic EL device according to claim 11, wherein the polymer contains at least one species of structure units represented by the following general formulas (1) to (4): 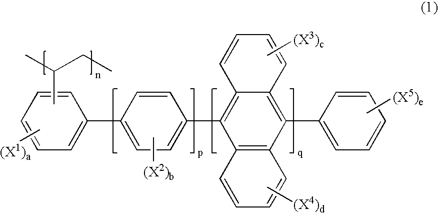
where X¹, X², X³, X⁴, and X⁵ are either identical or different from each other, each representing an alkyl group, alkoxy group, aryl group, aryloxy group, heterocyclic group, halogen atom, cyano group, hydroxyl group, or amino group; a, b, c, and d are integers of 0 to 4; e is an integer of 0 to 5; p is 0 or 1; and q is an integer of 1 to 3; 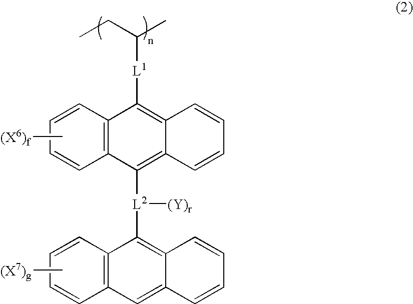
where L¹ is a bivalent organic group; L² is a bivalent aliphatic hydrocarbon group with a carbon number of 1 to 4, an aromatic group having a valence of (r+2) with a carbon number of 6 to 13, or an imino group; Y, X⁶, and X⁷ are independently univalent substituents; f is an integer of 0 to 8; g is an integer of 0 to 9; r is an integer of 0 or 1; and n is an integer of at least 1; 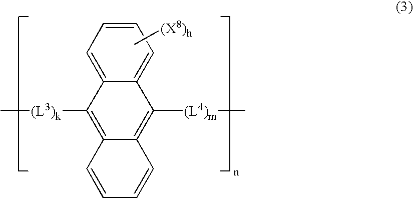
where L³ and L⁴ are bivalent organic groups; X⁸ is an alkyl group, alkoxy group, aryl group, aryloxy group, heterocyclic group, halogen atom, cyano group, hydroxyl group, or amino group; h is an integer of 0 to 8; k and m are each 0 or 1, while (k+m) is at least 1; and n is an integer of at least 1; and 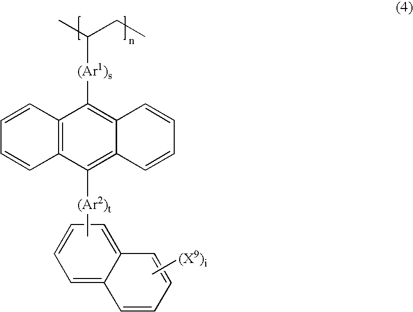
where Ar¹ and Ar² are either identical or different from each other, each representing a substituted or unsubstituted phenylene group or substituted or unsubstituted naphthylene group; X⁹ is an alkyl group, alkoxy group, aryl group, aryloxy group, heterocyclic group, halogen atom, cyano group, hydroxyl group, or amino group; s is 1 or 2; t is 0 or 1; i is an integer of 0 to 7; and n is an integer of at least 1.

15. An organic EL device according to claim 11, wherein the hole-blocking compound is at least one species selected from polar polymer compounds and organic metal compounds.

16. An organic EL device according to claim 15, wherein the polar polymer compound is at least one species of organic polymer compound selected from the group consisting of the following organic polymer compounds (a) to (c) either having a substituent or not:
(a) polymers or copolymers of compounds selected from the group consisting of vinylpyridine, (meth)acrylic acid, N-alkylacrylamide, N,N-dialkylacrylamide, hydroxy(meth)acrylate, vinyl acetate, styrene, and N-vinylpyrrolidone;
(b) oxyalkylene polymers or copolymers having an alkyl group with a carbon number of 2 to 4; and
(c) polyoxazoline or polyvinylbutyral.

17. An organic EL device according to claim 15, wherein the polar polymer compound is at least one organic polymer compound selected from the group consisting of poly(2-vinylpyridine), poly(4-vinylpyridine), polyacrylic acid, polymethacrylic acid, poly(N,N-dimethylacrylamide), poly(2-hydroxyethyl acrylate), poly(2-hydroxyethyl methacrylate), poly-N-vinylpyrrolidone, polyvinyl acetate, polystyrene, substituted polystyrene, polyethylene glycol, polypropylene glycol, poly(tetramethylene ether) glycol, poly(2-ethyl-2-oxazoline), and polyvinyl butyral.

18. An organic EL device according to claim 11, wherein the electron-blocking layer contains a polymer compound having a triphenylamine structure with an electron affinity of 3.0 eV or less.

19. An organic EL device according to claim 11, wherein the luminescent layer further contains a hole-transferring compound having a glass transition temperature of at least 70° C.

20. A method of manufacturing an organic EL device comprising a hole injection electrode and an electron injection electrode disposed so as to oppose each other; a luminescent layer, disposed between the hole injection electrode and electron injection electrode, containing a polymer having an anthracene structure and a modified part, disposed near a surface on the side closer to the electron injection electrode, containing a hole-blocking compound having a bandgap of at least 4.0 eV; and an electron-blocking layer, disposed between the hole injection electrode and luminescent layer, containing a hole-transferring compound having an electron affinity of 3.0 eV or less;
the method comprising the step of forming a coating film by a coating method using a coating liquid containing the polymer, and further applying a coating liquid containing the hole-blocking compound onto a surface of the coating film on the side closer to the electron injection electrode, so as to form the modified part, thereby providing the luminescent layer.

21. An organic EL display comprising:
a display part having a plurality of organic EL devices arranged therein, each organic EL device comprising a hole injection electrode and an electron injection electrode disposed so as to oppose each other, a luminescent layer, disposed between the hole injection electrode and electron injection electrode, containing a polymer having an anthracene structure and a modified part, disposed near a surface on the side closer to the electron injection electrode, containing a hole-blocking compound having a bandgap of at least 4.0 eV, and an electron-blocking layer, disposed between the hole injection electrode and luminescent layer, containing a hole-transferring compound having an electron affinity of 3.0 eV or less;
a power supply part, electrically connected to each of the pair of electrodes, for supplying a voltage or current to the electrodes; and
a switching part for turning on/off the organic EL devices.
